(19) United States
(12) Patent Application Publication
(10) Pub. No.: US 2019/0129036 A1
(43) Pub. Date: May 2, 2019

(54) DETECTOR FOR AN OPTICAL DETECTION OF AT LEAST ONE OBJECT

(71) Applicant: trinamiX GmbH, Ludwigshafen (DE)

(72) Inventors: Sebastian VALOUCH, Ludwigshafen (DE); Wilfried HERMES, Ludwigshafen (DE); Christoph LUNGENSCHMIED, Ludwigshafen (DE); Robert SEND, Ludwigshafen (DE); Ingmar BRUDER, Ludwigshafen (DE)

(73) Assignee: trinamiX GmbH, Ludwigshafen (DE)

(21) Appl. No.: 16/094,402

(22) PCT Filed: Apr. 18, 2017
(86) PCT No.: PCT/EP2017/059114

§ 371 Date: Oct. 17, 2018

(30) Foreign Application Priority Data
Apr. 19, 2016 (EP) 16165905.7

(51) Int. Cl. G01S 17/66; G01S 17/42; G01S 7/481; H01L 51/42; H01L 51/44; H01L 51/00

(52) U.S. Cl. CPC G01S 17/66; G01S 17/42; G01S 7/4816; H01L 51/0037; H01L 51/426; H01L 51/4273; H01L 51/445; H01L 51/4206

(57) ABSTRACT

A detector for an optical detection of at least one object. The detector includes: at least one transversal optical sensor configured to determine a transversal position of a light beam traveling from the object to the detector, the transversal optical sensor including: at least one photovoltaic layer embedded between at least two conductive layers, the photovoltaic layer including a plurality of quantum dots, the at least one transversal sensor signal indicating a transversal position of the light beam in the photovoltaic layer; and at least one evaluation device configured to generate at least one item of information on a transversal position of the object by evaluating the at least one transversal sensor signal.

### FIELD OF THE INVENTION

The invention relates to a detector for an optical detection of at least one object, in particular, for determining a position of at least one object, specifically a lateral position of the at least one object. Furthermore, the invention relates to a human-machine interface, an entertainment device, a tracking system, a scanning system, and a camera. Further, the invention relates to a method for optical detection of at least one object and to various uses of the detector. Such devices, methods and uses can be employed for example in various areas of daily life, gaming, traffic technology, mapping of spaces, production technology, security technology, medical technology or in the sciences. However, further applications are possible.

### PRIOR ART

A large number of optical sensors and photovoltaic devices are known from the prior art. While photovoltaic devices are generally used to convert electromagnetic radiation, for example, ultra-violet, visible or infrared light, into electrical signals or electrical energy, optical detectors are generally used for picking up image information, such as a position of a radiating or illuminated object, and/or for detecting at least one optical parameter, for example, a brightness.

Various detectors for optically detecting a lateral position of at least one object are known on the basis of optical sensors. In general, image sensors based on CMOS or CCD technology can be used for analyzing the position of a light spot. However, in order to enhance a lateral resolution by reduced costs position-sensitive sensors are used increasingly. Herein, the position-sensitive diodes utilize that a generated photocurrent may exhibit a lateral division. In a way as known from the state of the art, the term “position sensitive detector” or “PSD”, thus, usually refers to an optical detector that may employ silicon based diodes for determining a position of a focus of an incident light beam. Consequently, a light spot on a surface area of the PSD may generate electrical signals corresponding to a position of the light spot on the surface area, wherein the position of the light spot may, particularly, be determined from a relationship between at least two electrical signals. Based on intransparent optical properties of the silicon material as employed in this kind of PSD, transversal optical sensors which utilize position-sensitive silicon diodes are, however, intransparent optical sensors, an observation that may be capable of severely limiting their range of applicability.

In U.S. Pat. No. 6,995,445 and US 2007/0176165 A1, a position sensitive organic detector is disclosed. Therein, a resistive bottom electrode, is used which is electrically contacted by using at least two electrical contacts. By forming a current ratio of the currents from the electric contacts, a position of a light spot on the organic detector may be detected.

WO 2014/097181 A1, the full content of which is herewith included by reference, discloses a method and a detector for determining a position of at least one object, by using at least one longitudinal optical sensor and at least one transversal optical sensor. Specifically, the use of sensor stacks is disclosed, in order to determine both a longitudinal position and at least one lateral position of the object with a high degree of accuracy and without ambiguity. Herein, the transversal optical sensor is a photo detector having at least one first electrode, at least one second electrode and at least one photovoltaic material, wherein the photovoltaic material is embedded in between the first electrode and the second electrode. For this purpose, the transversal optical sensor is or comprises one or more dye-sensitized organic solar cells (DSCs, also referred to as dye solar cells), such as one or more solid dye-sensitized organic solar cells (s-DSCs). However, known transversal optical sensors that employ these kinds of materials can, in general, only be used for the optical detection of wavelengths below 1000 nm. Due to their inefficiency for wavelengths above 1000 nm an upconversion material is usually required. As a result, such transversal optical sensors may be inefficient enough to be used for an optical detection within the infrared spectral range. Further, WO 2014/097181 A1 discloses a human-machine interface, an entertainment device, a tracking system, and a camera, each comprising at least one such detector for determining a position of at least one object.

PCT patent application No. PCT/EP2016/051817, filed Jan. 28, 2016, the full content of which is herewith included by reference, discloses a longitudinal optical sensor. Herein, a sensor region of the longitudinal optical sensor comprises a photoconductive material, wherein an electrical conductivity in the photoconductive material, given the same total power of the illumination, is dependent on the beam cross-section of the light beam in the sensor region. Thus, the longitudinal sensor signal is dependent on the electrical conductivity of the photo-conductive material. The longitudinal optical sensor comprises a layer of the photoconductive material and two electrodes contacting the layer. Herein, the photoconductive material may, preferably, be selected from the group comprising lead sulfide (PbS), lead selenide (PbSe), lead telluride (PbTe), cadmium telluride (CdTe), indium phosphide (InP), cadmium sulfide (CdS), cadmium selenide (CdSe), indium antimonide (InSb), mercury cadmium telluride (HgCdTe; MCT), copper indium sulfide (CIS), copper indium gallium selenide (GIGS), zinc sulfide (ZnS), zinc selenide (ZnSe), a perovskite structure materials ABCs, wherein A denotes an alkaline metal or an organic cation, B=Pb, Sn, or Cu, and C a halide, and copper zinc tin sulfide (CZTS). Further, solid solutions and/or doped variants of the mentioned compounds or of other compounds of this kind may also be feasible. Core shell structures of the materials of this kind of materials may also be feasible. In a special embodiment, the photoconductive material is provided in form of a thin colloidal film comprising quantum dots, wherein the thin film is arranged between two individual conductive layers. Additionally, a Schottky barrier may form at an interface between the thin film and one of the conductive layers. Further, a blocking layer for electrons or holes may, additionally, be arranged between one of the conductive layers and the thin film.

J. P. Clifford, G. Konstantatos, K. W. Johnston, S. Hoogland, L. Levina, and E. H. Sargent, Fast, sensitive and spectrally tunable colloidal quantum-dot photodetectors, Nature Nanotechnology 4, Jan. 2009, describe ultrasensitive photodetectors based on solution-process colloidal quantum dots (CQD) operating in both the visible and infrared. Accordingly, a spacing between individual CQDs may be controlled by a length of an organic ligand used to passivate their surfaces, which has been proved to be a determining factor with respect to a charge-carrier mobility and, consequently, a conductivity of CQD films. Contrary to state-of-the-art devices which either exhibit considerably long response times on the scale of seconds for changes with respect to the illumination or suffer from a low sensitivity, the authors show that the temporal response of CQD devices is determined by two components, i.e. electron drift, being a fast process, and electron diffusion, being a slow process. Taking this observation into account, tunable CQD photodiodes operable in the visible and/or the infrared spectral range capable of excluding the diffusion component, which exhibit a considerable improvement with respect to the product of sensitivity and bandwidth, have been provided. For this purpose, photodiodes based on a Schottky barrier at an interface between a PbS CQD film and an aluminum contact have been used, wherein a planar, transparent indium tin oxide (ITO) thin film on a glass substrate forms an opposing Ohmic contact. An incident light beam through the glass substrate generates electrons and holes in the CQD film which are collected at the aluminum contact and the ITO film, respectively. As a result, a depletion region may form in the CQD film at a metal-CQD interface, whereas the remaining volume of the CQD film may be considered as a p-type semiconductor. Herein, the PbS CQDs used had diameters of approx. 6 nm, thus, providing an increased value of 0.86 eV for an effective bandgap (compared to 0.42 eV for bulk PbS), which results in an absorption feature around 1450 nm.

A. G. Pattantyus-Abraham, I. J. Kramer, A. R. Barkhouse, X. Wang, G. Konstantatos, R. Debnath, L. Levina, I. Raabe, M. K. Nazeeruddin, M. Gratzel, and E. H. Sargent, Depleted-Heterojunction Colloidal Quantum Dot Solar Cells, ACS NANO 4 (6), May 24, 2010, describe colloidal quantum dot (CQD) photovoltaics combining low-cost solution processability with quantum size-effect tunability to match absorption with the solar spectrum. Two distinct device architectures and operating mechanisms are presented. A Schottky device is optimized and explained in terms of a depletion region driving electron-hole pair separation on the semiconductor side of a junction between an opaque low-work-function metal and a p-type CQD film. An excitonic device employing a CQD layer atop a transparent conductive oxide (TCO) is explained in terms of diffusive exciton transport via energy transfer followed by exciton separation at the type-II heterointerface between the CQD film and the TCO. Further CQD photovoltaic devices on TCOs rely on the establishment of a depletion region for field-driven charge transport and separation, and also exploit the large bandgap of the TCO to improve rectification and block undesired hole extraction. CQD solar cell devices have harvested photons at wavelengths as long as 1800 nm, thereby exhibiting short-circuit current densities as high as 25 mA/cm².

G. H. Carey, A. L. Abdelhady, Z. Ning, S. M. Thon, O. M. Bakr, and E. H. Sargent, Colloidal Quantum Dot Solar Cells, Chem. Rev. 115 (23), 2015, pp 12732-12763, provide a review concerning photovoltaic devices comprising doped semiconductor CQD films which are combined, along with asymmetric electrodes, with a metal or with another semiconductor in order to generate a complete solar cell. As a result, a Schottky barrier cell may be obtained with the metal, while the at least two semiconductors may, preferably, combine into at least one of a CQD-CQD pn-junction, a CQD-titanium dioxide pn-junction, or a CQD-CQD-zinc oxide pin-junction. Herein, the state of the art related to synthesizing quantum dot solutions which may comprise desired properties with respect to band gap, absorption, and dispersity; converting the solutions into CQD films which may comprise desired properties with regard to quantum dot packing, surface passivation, absorption, and conductivity; and constructing material stacks around the CQD film for generating the complete solar cell are addressed.

R. Martins and E. Fortunato, Thin Film Position Sensitive Detectors: from 1D to 3D Applications, Chap. 8 in R. A. Street (Ed.), Technology and Applications of Amorphous Silicon, Springer, 2010, provide a review of 1 D, 2D and 3D thin film position sensitive detectors (TFPSD) comprising hydrogenated amorphous silicon (a-Si:H), including technical implications of fabrication processes and physics ruling their behaviors.

This discussion of known concepts, such as the concepts of several of the above-mentioned prior art documents, clearly shows that some technical challenges remain. Specifically, there is further room for improvement in terms of increased accuracy of position detectors for distance measurements, for two-dimensional sensing or even for three-dimensional sensing. Further, complexity of the optical systems still remains an issue which may be addressed.

### Problem Addressed by the Invention

Therefore, a problem addressed by the present invention is that of specifying a device and a method for optically detecting at least one object which at least substantially avoid the disadvantages of known devices and methods of this type. In particular, an improved simple, cost-efficient, at least partially transparent and, still, reliable transversal detector for determining the lateral position of an object not only by using light beams in the visible spectral range but also in the infrared spectral range, in particular for wavelengths of 1000 nm and above, would rather be desirable.

### SUMMARY OF THE INVENTION

This problem is solved by the invention with the features of the independent patent claims. Advantageous developments of the invention, which can be realized individually or in combination, are presented in the dependent claims and/or in the following specification and detailed embodiments.

As used herein, the expressions “have”, “comprise” and “contain” as well as grammatical variations thereof are used in a non-exclusive way. Thus, the expression “A has B” as well as the expression “A comprises B” or “A contains B” may both refer to the fact that, besides B, A contains one or more further components and/or constituents, and to the case in which, besides B, no other components, constituents or elements are present in A.

In a first aspect of the present invention, a detector for optical detection, in particular, for determining a position of at least one object, specifically a lateral position of the at least one object, is disclosed.

The “object” generally may be an arbitrary object, chosen from a living object and a non-living object. Thus, as an example, the at least one object may comprise one or more articles and/or one or more parts of an article. Additionally or alternatively, the object may be or may comprise one or more living beings and/or one or more parts thereof, such as one or more body parts of a human being, e.g. a user, and/or an animal.

As used herein, a “position” generally refers to an arbitrary item of information on a location and/or orientation of the object in space. For this purpose, as an example, one or more coordinate systems may be used, and the position of the object may be determined by using one, two, three or more coordinates. As an example, one or more Cartesian coordinate systems and/or other types of coordinate systems may be used. In one example, the coordinate system may be a coordinate system of the detector in which the detector has a predetermined position and/or orientation. As will be outlined in further detail below, the detector may have an optical axis, which may constitute a main direction of view of the detector. The optical axis may form an axis of the coordinate system, such as a z-axis. Further, one or more lateral axes may be provided, preferably perpendicular to the z-axis.

Thus, as an example, the detector may constitute a coordinate system in which the optical axis forms the z-axis and in which, additionally, an x-axis and a y-axis may be provided which are perpendicular to the z-axis and which are perpendicular to each other. As an example, the detector and/or a part of the detector may rest at a specific point in this coordinate system, such as at the origin of this coordinate system. In this coordinate system, a direction parallel or antiparallel to the z-axis may be regarded as a longitudinal direction, and a coordinate along the z-axis may be considered as a longitudinal coordinate. An arbitrary direction perpendicular to the longitudinal direction may be considered as a lateral or a transversal direction, and an x- and/or y-coordinate may be considered as a lateral or a transversal coordinate.

Alternatively, other types of coordinate systems may be used. Thus, as an example, a polar coordinate system may be used in which the optical axis forms a z-axis and in which a distance from the z-axis and a polar angle may be used as additional coordinates. Again, a direction parallel or antiparallel to the z-axis may be considered a longitudinal direction, and a coordinate along the z-axis may be considered a longitudinal coordinate. Any direction perpendicular to the z-axis may be considered a lateral or a transversal direction, and the polar coordinate and/or the polar angle may be considered a lateral or a transversal coordinate.

As used herein, the detector for optical detection generally is a device which is adapted for providing at least one item of information on the position of the at least one object, in particular on the lateral or transversal position of the at least one object. The detector may be a stationary device or a mobile device. Further, the detector may be a stand-alone device or may form part of another device, such as a computer, a vehicle or any other device. Further, the detector may be a hand-held device. Other embodiments of the detector are feasible.

The detector may be adapted to provide the at least one item of information on the position of the at least one object, in particular of the lateral or transversal position of the at least one object, in any feasible way. Thus, the information may e.g. be provided electronically, visually, acoustically or in any arbitrary combination thereof. The information may further be stored in a data storage of the detector or a separate device and/or may be provided via at least one interface, such as a wireless interface and/or a wire-bound interface.

The detector for an optical detection of at least one object according to the present invention comprises:
at least one transversal optical sensor, the transversal optical sensor being adapted to determine a transversal position of a light beam traveling from the object to the detector, wherein the transversal position is a position in at least one dimension perpendicular to an optical axis of the detector, wherein the transversal optical sensor has at least one photovoltaic layer embedded between at least two conductive layers, wherein the photovoltaic layer comprises a plurality of quantum dots, wherein at least one of the conductive layers is at least partially transparent allowing the light beam to travel to the photovoltaic layer, wherein the transversal optical sensor further has at least one split electrode located at one of the conductive layers, wherein the split electrode has at least two partial electrodes adapted to generate at least one transversal sensor signal, wherein the at least one transversal sensor signal indicates the transversal position of the light beam in the photovoltaic layer; and
at least one evaluation device, wherein the evaluation device is designed to generate at least one item of information on a transversal position of the object by evaluating the at least one transversal sensor signal.

Herein, the components listed above may be separate components. Alternatively, two or more of the components as listed above may be integrated into one component. Further, the at least one evaluation device may be formed as a separate evaluation device independent from the transfer device and the transversal optical sensors, but may preferably be connected to the transversal optical sensor in order to receive the transversal sensor signal. Alternatively, the at least one evaluation device may fully or partially be integrated into the at least one transversal optical sensor.

As used herein, the term “transversal optical sensor” generally refers to a device which is adapted to determine a transversal or lateral position of at least one light beam traveling from the object to the detector. With regard to the term position, reference may be made to the definition above. Thus, preferably, the transversal position may be or may comprise at least one coordinate in at least one dimension perpendicular to an optical axis of the detector. As an example, the transversal position may be a position of a light spot generated by the light beam in a plane perpendicular to the optical axis, such as on a light-sensitive sensor surface of the transversal optical sensor. As an example, the position in the plane may be given in Cartesian coordinates and/or polar coordinates. Other embodiments are feasible.

Herein, the transversal optical sensor may, preferably, be configured in order to function as a “position sensitive detector” or a “position sensing detector”, both commonly abbreviated to the term, “PSD”, by being capable of providing both of the two lateral components of the spatial position of the object, in particular, simultaneously. As a result, by combining the at least one transversal coordinate of the object with the at least one longitudinal coordinate of the object a three-dimensional position of the object as defined above may, thus, be determined by using the evaluation device. It is also possible that the transversal sensor is able to detect the longitudinal coordinate.

The transversal optical sensor may provide at least one transversal sensor signal. Herein, the transversal sensor signal may generally be an arbitrary signal indicative of the transversal or a lateral position. As an example, the transversal sensor signal may be or may comprise a digital and/or an analog signal. As an example, the transversal sensor signal may be or may comprise a voltage signal and/or a current signal. Additionally or alternatively, the transversal sensor signal may be or may comprise digital data related to the voltage signal or the current signal, respectively. The transversal sensor signal may comprise a single signal value and/or a series of signal values. The transversal sensor signal may further comprise an arbitrary signal which may be derived by combining two or more individual signals, such as by averaging two or more signals and/or by forming a quotient of two or more signals.

According to the present invention, the transversal optical sensor has at least one photovoltaic layer which is embedded between at least two conductive layers, wherein a single photovoltaic layer being embedded between two individual conductive layers may particularly be preferred. As generally used, the term “layer” refers to refers to an element having an elongated shape and a thickness, wherein an extension of the element in a lateral dimension exceeds the thickness of the element, such as by at least a factor of 10, preferably of 20, more preferably of 50 and most preferably of 100 or more.

In a particularly preferred embodiment, at least one of the at least two conductive layers or, alternatively or in addition, at least one additional intermediate layer may exhibit a sheet resistance of 500 Ω/sq to 20 000 Ω/sq, preferably of 1000 Ω/sq to 15 000 Ω/sq. As generally used, the unit “Ω/sq” is dimensionally equal to the SI unit Ω but exclusively reserved for the sheet resistance. By way of example, a square sheet having the sheet resistance of 10 Ω/sq has an actual resistance of 10 Ω, regardless of the size of the square. As a result of the sheet resistance being in the indicated range, the photovoltaic layer embedded between the at least two conductive layers and equipped with the at least one split electrode may act as the transversal detector. Herein, as described below in more detail, at least one of the conductive layers is at least partially transparent in at least a partition of the electromagnetic spectrum, preferably in the partition of the electromagnetic spectrum in which a material within the photovoltaic layer may be able to generate charge carriers by interacting with electromagnetic radiation transmitted through the transparent conductive layer. By way of example, the transparent conductive layer may comprise a transparent conductive materials, preferably a transparent conductive oxide (TCO) as described below in more detail. Further, a plurality of quantum dots is present within the photovoltaic layer. As generally used, the term “quantum dots” refers to a state of a material in which the material may comprise electrically conducting particles, such as electrons or holes, which are confined in all three spatial dimensions to a considerably small volume that is usually denominated as a “dot”. Herein, the quantum dots may exhibit a size which can, for simplicity, be considered as diameter of a sphere that might approximate the mentioned volume of the particles. In this preferred embodiment, the quantum dots may comprise nanometer-scale crystals which, in particular, may exhibit a size from 1 nm to 100 nm, preferably from 2 nm to 100 nm, more preferred from 2 nm to 15 nm. Consequently, the thin film which comprises the quantum dots, may, preferably exhibit a thickness from 1 nm to 100 nm, preferably from 2 nm to 100 nm, more preferred from 2 nm to 15 nm, provided that the quantum dots actually comprised in a specific thin film may exhibit a size being below the thickness of the specific thin film. In a further preferred embodiment, an application of temperature above room-temperature may lead to a formation of agglomerates of the nanometer-scale crystals, a process which may also be denominated as “necking”, whereby sub-micrometer-scale crystals, which may exhibit a thickness from 100 nm to below 1 μm, may be obtained. In this embodiment, the thin film which comprises sub-micrometer-scale agglomerations of quantum dots, may, preferably exhibit a thickness from 1000 nm to 1 μm, provided that the agglomerations actually comprised in the specific thin film may exhibit a size being below the thickness of the specific thin film. Further, the term “plurality” may indicate here that a large number of quantum dots, may be present within the layer, wherein at least some of the quantum dots may stick together, thereby forming an agglomerate that may comprise a multitude of quantum dots.

Further, the photovoltaic layer may, preferably, be obtainable by using a colloidal film which comprises the plurality of the quantum dots being provided for producing the photovoltaic layer. As used herein, the term “colloidal film” refers to a chemical mixture comprising a medium, particularly at least one organic compound, in which the insoluble quantum dot nanoparticles may be dispersed throughout the medium. In contrast to a solution, in which a solute and a solvent constitute a single phase, a stable phase separation is maintained within the colloidal film in a fashion that the dispersed quantum dot nanoparticles constitute a dispersed phase while the medium constitutes a continuous phase. Herein, the medium in the continuous phase comprises at least one nonpolar organic solvent, wherein the nonpolar organic solvent is, preferably, selected from the group comprising octane, toluene, cyclohexane, n-heptane, benzene, chlorobenzene, acetonitrile, dimethylformamide (DMF), and chloroform.

In a particularly preferred embodiment, the colloidal film may, thus, comprise nanometer-scale semiconductor crystals which may, in addition, be capped with cross-linking molecules. Herein, the cross-linking molecules may be selected, on one hand, to provide a cohesion between the individual quantum dots within the colloidal film and, on the other hand, to simultaneously allow determining an average distance between the individual quantum dots within the colloidal film, in particular, as a result from the approximate spatial extension of the selected cross-linking molecules. For this purpose, the cross-linking molecules may comprise an organic agent, wherein the organic agent may, particularly, be selected from the group comprising thioles and amines, preferably, from the group comprising 1,2-ethanedithiol (edt), 1,2- and 1,3-benzenedi-thiol (bdt), and butylamine. Thus, depending on the ligands, the quantum dots may exhibit hydrophilic or hydrophobic properties.

The quantum dots can be produced by applying a gas-phase, a liquid-phase, or a solid-phase approach. Hereby, various ways for a synthesis of the quantum dots are possible, in particular by employing known processes such as thermal spraying, colloidal synthesis, or plasma synthesis. In order to obtain the photovoltaic layer, the colloidal film comprising the plurality of the quantum dots may be treated in a manner that the continuous phase comprising the medium and, if, applicable, the additional cross-linking molecules, may be removed, in particular by applying a heat treatment to these organic compounds, in a fashion that the plurality of the quantum dots may be maintained. Thus, colloidal quantum dots (CQD) may be obtainable from a heat treatment of the colloidal film. By way of example, the heat treatment for PbS CQD may comprise applying a temperature from 50° C. to 250° C., preferably from 80° C. to 220° C., more preferred from 100° C. to 200° C., in air and can be done in different atmospheres such as air, nitrogen, argon or vacuum. Further details with respect to the production process will be described below in more detail. However, other production processes and parameter ranges may also be feasible, in particular depending on the kind of CQDs used. Irrespective of the details of the production process, the quantum dots within the photovoltaic layer may, thus, assume a state which may also be denominated as colloidal quantum dots (CQD).

Further, as generally used, the term “photovoltaic material” refers to a material in which an illumination of the material by an incident light beam may generate charge carriers providing a photoelectric current or a photoelectric voltage to be determined. As an example, when a light beam may be incident upon the photovoltaic material, the electrons which may be present in a valence band of the material may absorb energy and, thus being excited, may jump to the conduction band where they may behave as free conductive electrons. Consequently, no bias voltage may be required for observing this effect. This is in contrast to a photoconductive material in which the resistivity of the sensor region may be varied by the illumination of the corresponding sensor region, whereby the observable change in electrical conductivity of the material may be monitored by a variation in a voltage applied across the material or in an alteration of the value of a current applied through the material, such as by an application of a bias voltage across the material.

However, the colloidal quantum dots (CQD) which comprise a composition that may, in a bulk volume, usually be considered as photoconductive material may, nevertheless, exhibit slightly or significantly modified chemical and/or physical properties with respect to a homogeneous layer comprising the same material. Thus, in a particularly preferred embodiment of the present invention, the photovoltaic material as used for the plurality of the quantum dots may be selected from a material which, being used in a homogeneous layer comprising a bulk volume, may usually be denominated as a photoconductive material. Herein, the material in form of the colloidal quantum dots may, in particular, exhibit a higher electrical resistance compared to the same material as homogeneously distributed over the same layer and may, thus, assure that no short circuit between the adjacent conductive layers through the colloidal quantum dot layer may be observable. Moreover, no bias voltage may be required in order to generate the charge carriers which may provide the photoelectric current or the photoelectric voltage to be determined. Consequently, it may be justified to denominate the layer comprising the colloidal quantum dots the “photovoltaic layer”.

More particular, the photovoltaic material as used for the quantum dots may, preferably, be selected from the group comprising lead sulfide (PbS), lead selenide (PbSe), lead telluride (PbTe), cadmium telluride (CdTe), indium phosphide (InP), cadmium sulfide (CdS), cadmium selenide (CdSe), indium antimonide (InSb), mercury cadmium telluride (HgCdTe; MCT), copper indium sulfide (CIS), copper indium gallium selenide (CIGS), zinc sulfide (ZnS), zinc selenide (ZnSe), a perovskite structure materials ABC₃, wherein A denotes an alkaline metal or an organic cation, B =Pb, Sn, or Cu, and C a halide, and copper zinc tin sulfide (CZTS). Further, solid solutions and/or doped variants of the mentioned compounds or of other compounds of this kind may also be feasible. Core shell structures of the materials of this kind of materials may also be feasible. However, other kinds of materials may also be feasible.

For the purposes of the present invention, the photovoltaic material as used for providing the plurality of the quantum dots in the colloidal film of the transversal optical sensor may, thus, preferably comprise an inorganic material, a combination, a solid solution and/or a doped variant thereof, in form of the sub-micrometer-scale crystals as described above. As used herein, the term “solid solution” refers to a state of the material in which at least one solute may be comprised in a solvent, whereby a homogeneous phase is formed and wherein the crystal structure of the solvent may, generally, be unaltered by the presence of the solute. By way of example, the binary CdTe may be solved in ZnTe leading to Cd₁₋ₓZnₓTe, wherein x can vary from 0 to 1. As further used herein, the term “doped variant” may refer to a state of the material in which single atoms apart from the constituents of the material itself are introduced onto sites within the crystal which are occupied by intrinsic atoms in the undoped state. As generally known, a pure silicon crystal may be doped with one or more of boron, aluminum, gallium, indium, phosphorous, arsenic, antimony, germanium, or other atoms, particularly, in order to modify the chemical and/or physical properties of the silicon crystal.

In this regard, the inorganic material as used for providing the quantum dots may, in particular, comprise one or more of a group II-VI compound, i.e. a chemical compound with, on one hand, at least one group II element or at least one group XII element and, on the other hand, at least one group VI element, in particular a chalcogenide, or a group III-V compound, i.e. a chemical compound with at least one group III element and at least one group V element, in particular, a pnictogenide, as well as a combination, a solid solution and/or a doped variant thereof. However, other inorganic materials may equally be appropriate.

Preferably, the chalcogenide may be selected from the group comprising sulfide chalcogenides, selenide chalcogenides, telluride chalcogenides, ternary chalcogenides, quaternary and higher chalcogenides. As generally used, the term “chalcogenide” refers to a chemical compound which comprises a sulfide, a selenide, or a telluride anion. Preferably, the pnictogenide may be selected from the group comprising nitride pnictogenides, phosphide pnictogenides, arsenide pnictogenides, antimonide pnictogenides, ternary pnictogenides, quarternary and higher pnictogenides. As generally used, the term “pnictogenide” refers to a chemical compound which comprises a nitride, a phosphide, an arsenide, an antimonide or a bismuthide anion.

With regard to materials particularly suitable for the purpose of providing an optical detector for the infrared spectral range, the sulfide chalcogenide which may be used for the quantum dots may, most preferably, be selected from lead sulfide (PbS) or zinc sulfide (ZnS), the selenide chalcogenide from lead selenide (PbSe), cadmium selenide (CdSe), or zinc selenide (ZnSe), the ternary chalcogenide from mercury cadmium telluride (HgCdTe), mercury zinc telluride (HgZnTe), or mercury cadmium sulfide (HgCdS), while the nitride pnictogenide may especially be selected from indium nitride (InN), gallium nitride (GaN), or indium gallium nitride (InGaN), the phosphide pnictogenide from indium phosphide (InP), gallium phosphide (GaP), or indium gallium phosphide (InGaP), the arsenic pnictogenide from indium arsenide (InAs), gallium arsenide (GaAs), or indium gallium arsenide (InGaAs), the antimonide pnictogenide from indium antimonide (InSb), gallium antimonide (GaSb), or indium gallium antimonide (InGaSb), and the ternay pnictogenide from indium gallium phosphide (InGaP), gallium arsenide phosphide (GaAsP), or aluminum gallium phosphide (AlGaP).

Furthermore, the sulfide chalcogenide may, preferably, be selected from a group comprising lead sulfide (PbS), cadmium sulfide (CdS), zinc sulfide (ZnS), mercury sulfide (HgS), silver sulfide (Ag₂S), manganese sulfide (MnS), bismuth trisulfide (Bi₂S₃), antimony trisulfide (Sb₂S₃), arsenic trisulfide (As₂S₃), tin (II) sulfide (SnS), tin (IV) disulfide (SnS₂), indium sulfide (In₂S₃), copper sulfide (CuS or Cu₂S), cobalt sulfide (CoS), nickel sulfide (NiS), molybdenum disulfide (MoS₂), iron disulfide (FeS₂), and chromium trisulfide (CrS₃).

Further, the selenide chalcogenide may, preferably, be selected from a group comprising lead selenide (PbSe), cadmium selenide (CdSe), zinc selenide (ZnSe), bismuth triselenide (Bi₂Se₃), mercury selenide (HgSe), antimony triselenide (Sb₂Se₃), arsenic triselenide (As₂Se₃), nickel selenide (NiSe), thallium selenide (TISe), copper selenide (CuSe or Cu₂Se), molybdenum diselenide (MoSe₂), tin selenide (SnSe), and cobalt selenide (CoSe), and indium selenide (In₂Se₃).

Further, the telluride chalcogenide may, preferably, be selected from a group comprising lead telluride (PbTe), cadmium telluride (CdTe), zinc telluride (ZnTe), mercury telluride (HgTe), bis-muth tritelluride (Bi₂Te₃), arsenic tritelluride (As₂Te₃), antimony tritelluride (Sb₂Te₃), nickel tell-uride (NiTe), thallium telluride (TITe), copper telluride (CuTe), molybdenum ditelluride (MoTe₂), tin telluride (SnTe), cobalt telluride (CoTe), silver telluride (Ag₂Te), and indium telluride (In₂Te₃).

Further, the ternary chalcogenide may, preferably, be selected from a group comprising mercury cadmium telluride (HgCdTe; MCT), mercury zinc telluride (HgZnTe), mercury cadmium sulfide (HgCdS), lead cadmium sulfide (PbCdS), lead mercury sulfide (PbHgS), copper indium disulfide (CuInS_{2;} CIS), cadmium sulfoselenide (CdSSe), zinc sulfoselenide (ZnSSe), thallous sulfoselenide (TISSe), cadmium zinc sulfide (CdZnS), cadmium chromium sulfide (CdCr₂S₄), mercury chromium sulfide (HgCr₂S₄), copper chromium sulfide (CuCr₂S₄), cadmium lead selenide (CdPbSe), copper indium diselenide (CuInSe₂), indium gallium arsenide (InGaAs), lead oxide sulfide (Pb₂OS), lead oxide selenide (Pb₂OSe), lead sulfoselenide (PbSSe), arsenic selenide telluride (As₂Se₂Te), indium gallium phosphide (InGaP), gallium arsenide phosphide (GaAsP), aluminum gallium phosphide (AlGaP), cadmium selenite (CdSeO₃), cadmium zinc telluride (CdZnTe), and cadmium zinc selenide (CdZnSe), further combinations by applying compounds from the above listed binary chalcogenides and/or binary III-V-compounds.

With regard to quaternary and higher chalcogenides, this kind of material may, preferably, be selected from a quaternary or a higher chalcogenide which may be known to exhibit suitable photovoltaic properties in the form of the quantum dots. In particular, a compound having a composition of Cu(In, Ga)S/Se₂ or of Cu₂ZnSn(S/Se)₄ may be feasible for this purpose.

Further, combinations and/or solid solutions and/or doped variants of the mentioned compounds or of other compounds of this kind may also be feasible.

As already mentioned above, the at least one photovoltaic layer is sandwiched by the at least two conductive layers. As mentioned above, each of the at least two conductive layers may, thus, be arranged in a fashion that a direct electrical contact between the respective conductive layer and the embedded photovoltaic layer may be achieved, particularly in order to acquire the transversal sensor signal with as little loss as possible, such as due to additional resistances between the adjacent layers as well. Thus, the two individual conductive layers may, preferably, be arranged in form of a sandwich structure, i.e. in a manner that the thin photovoltaic film may adjoin both of the two conductive layers while the two conductive layers may be separated from each other.

Herein, a first the conductive layer may, preferably, be selected to exhibit at least partially optically transparent properties in order to allow at least a partition of the incident light beam passing through the first conductive layer in order to reach the photovoltaic layer comprising the plurality of the quantum dots. For this purpose, the first conductive layer may, in particular, comprise an at least partially transparent metallically conducting or semiconducting material, preferably, be selected from the group comprising an at least partially transparent semiconducting metal oxide or a doped variant thereof. Herein, at least one transparent metal oxide, in particular, indium tin oxide (ITO), fluorine-doped tin oxide (SnO2:F; FTO), magnesium oxide (MgO), aluminum zinc oxide (AZO), antimony tin oxide (SnO_{2/}Sb₂O₅), or a perovskite transparent conductive oxide, such as SrVO₃, or CaVO₃, or, alternatively, metal nanowires, such as Ag nanowires, may, preferably, be used. As known to the skilled person, some of the transparent metal oxides may, depending on a degree of doping, be metallically conducting or semiconducting. However, other materials may also be feasible, in particular according to the desired transparent spectral range.

As described below in more detail, the transversal optical sensor comprises a split electrode with partial electrodes being arranged in a fashion that currents through the partial electrodes may be dependent on a position of the light beam within the photovoltaic layer. This effect can, in general, be achieved by Ohmic losses or resistive losses occurring on a way from a location of generation of electrical charges within the photovoltaic layer to the partial electrodes. Thus, in order to generate the Ohmic losses or the resistive losses on the way from the location of the generation of the electric charges to the partial electrodes, the second conductive layer may, preferably, exhibit a higher electrical resistance compared to the electrical resistance of the partial electrodes. Further, the second conductive layer may also be selected to exhibit at least partially optically transparent properties and may, thus, comprise a material selected from the semiconducting materials that may be used for the conductive layer as described above. However, a layer of a transparent electrically conducting organic polymer may, preferably, be employed for this purpose. Herein, poly(3,4-ethylenedioxythiophene) (PEDOT) or a dispersion of PEDOT and a polystyrene sulfonic acid (PEDOT:PSS) may be selected as the transparent electrically conducting polymer. On the other hand, in case one of the conductive layers may already be at least partially transparent, a larger variety of different materials, including optically intransparent materials, may be employed for the at least one other conductive layer.

In particular, for the purpose of recording the transversal optical signal, the transversal optical sensor comprises a split electrode having at least two partial electrodes. Thus, the transversal sensor signal may indicate a position of a light spot generated by the light beam within the photovoltaic layer of the transversal optical sensor as long as the conductive layer at which the split electrode is located may exhibit a higher electrical resistance compared to the electrical resistance of the corresponding split electrode.

Generally, as used herein, the term “partial electrode” refers to an electrode out of a plurality of electrodes, adapted for measuring at least one current and/or voltage signal, preferably independent from other partial electrodes. Thus, in case a plurality of partial electrodes is provided, the respective electrode is adapted to provide a plurality of electric potentials and/or electric currents and/or voltages via the at least two partial electrodes, which may be measured and/or used independently. Further, in particular for allowing a better electronic contact, the split electrode having the at least two partial electrodes which may each comprise a metal contact may be arranged on top of one of the conductive layers, preferably, on top of the electrically conducting polymer. However, other kinds of arrangements of the split electrode within the transversal optical sensor may also be feasible. Herein, the metal contact may, preferably, be one of an evaporated contact or a sputtered contact or, alternatively, a printed contact or a coated contact, for which manufacturing a conductive ink may be employed.

The transversal optical sensor may further be adapted to generate the transversal sensor signal in accordance with the electrical currents through the partial electrodes. Thus, a ratio of electric currents through two horizontal partial electrodes may be formed, thereby generating an x-coordinate, and/or a ratio of electric currents through to vertical partial electrodes may be formed, thereby generating a y-coordinate. The detector, preferably the transversal optical sensor and/or the evaluation device, may be adapted to derive the information on the transversal position of the object from at least one ratio of the currents through the partial electrodes. Other ways of generating position coordinates by comparing currents through the partial electrodes are feasible.

The partial electrodes may generally be defined in various ways, in order to determine a position of the light beam in the photovoltaic layer. Thus, two or more horizontal partial electrodes may be provided in order to determine a horizontal coordinate or x-coordinate, and two or more vertical partial electrodes may be provided in order to determine a vertical coordinate or y-coordinate. In particular, in order to maintain as much area as possible for measuring the transversal position of the light beam, the partial electrodes may be provided at a rim of the transversal optical sensor, wherein an interior space of the transversal optical sensor is covered by the second conductive layer. Preferably, the split electrode may comprise four partial electrodes which are arranged at four sides of a square or a rectangular transversal optical sensor. Alternatively, the transversal optical sensor may be of a duo-lateral type, wherein the duo-lateral transversal optical sensor may comprise two separate split electrodes each being located at one of the two conductive layers which embed the photovoltaic layer, wherein each of the two conductive layers may exhibit a higher electrical resistance compared to the corresponding split electrode. However, other embodiments may also be feasible, in particular, depending on the form of the transversal optical sensor. As described above, the second conductive layer material may, preferably, be a transparent electrode material, such as a transparent conductive oxide and/or, most preferably, a transparent conductive polymer, which may exhibit a higher electrical resistance compared to the split electrode.

By using the transversal optical sensor, wherein one of the electrodes is the split electrode with the two or more partial electrodes, currents through the partial electrodes may be dependent on a position of the light beam within the photovoltaic layer, which may, thus, also be denominated as a “sensor area”. This kind of effect may generally be due to the fact that Ohmic losses or resistive losses may occur on the way from a location of generation of electrical charges within the photovoltaic layer that comprises the plurality of the quantum dots as a result of the impinging light onto the photovoltaic layer to the partial electrodes. Thus, due to the Ohmic losses on the way from the location of generation of the electric charges to the partial electrodes through the second conductive layer, the respective currents through the partial electrodes depend on the location of the generation of the electric charges and, thus, to the position of the light beam in the photovoltaic layer. In order to accomplish a closed circuit for the electrons and/or holes, the first conductive layer as described above may, preferably, be employed. For further details with regard to determining the position of the light beam, reference may be made to the preferred embodiments below, to the disclosure of WO 2014/097181 A1, the respective references cited therein, or to R. Martins and E. Fortunato, as cited above.

In a further special embodiment, a Schottky barrier may, additionally, form at an interface between the photovoltaic film comprising the quantum dots and one of the conductive layers which may exhibit properties which are sufficient for forming the Schottky barrier. As generally used, the term “Schottky barrier”, refers to an energy barrier for electrons or holes which may appear at a boundary layer between a semiconductor layer and an adjacent metal layer which may, in contrast to an Ohmic contact as described below in more detail, exhibit a rectifying characteristic, thus, allowing the electronic device comprising the Schottky barrier being used as a diode. By way of example, the incident light beam traversing the transparent conductive layer, such as the transparent indium tin oxide (ITO) electrode, may generate charge carriers, i.e. electrons and holes, within the photovoltaic film comprising the quantum dots. Further, the charge carriers may be collected at the boundaries towards both conductive layers, wherein the intransparent conductive layer may, preferably, be a metal electrode. As a result, a depletion region may form within the thin film towards one of the conductive layers, whereas the remaining volume of the photovoltaic layer may behave as a p-type semiconductor layer. By way of example, in case the photovoltaic layer may comprise PbS quantum dots, the corresponding conductive layer may comprise an aluminum electrode.

In a further special embodiment, a blocking layer may, additionally, be arranged between the transparent conductive layer and the photovoltaic layer comprising the quantum dots. As used herein, the term “blocking layer” refers to a thin layer which may be adapted to influence a path of permeating electrically conducting particles, in particular of electrons or holes, with respect to the adjacent layers in an electronic element, such as to prevent a short-circuiting of the adjacent layers or to prevent a recombination of permeating conductive particles as provided by one of the adjacent layers with oppositely charged particles, such as ions, located in the other of the adjacent layers. In this special embodiment, the blocking layer may, preferably, comprise a thin film of an electrically conducting material, in particular one or more of titanium dioxide (TiO₂) or zinc oxide (ZnO). However, in other embodiments an electron blocking layer, such as a layer of molybdenum oxide (MoO₃₋ₓ), may, alternatively, be employed for this purpose.

In a further special embodiment based on A. G. Pattantyus-Abraham et al., s.o., a nanoporous electrode layer, in particular a nanoporous titanium dioxide (TiO₂) electrode, may be sensitized with a thin layer of CQD, preferably, on the order of one monolayer. The so-called “CQD sensitized cell” which has been reported to exhibit power conversion efficiencies up to 3.2%, may, thus, being considered as comprising a thin layer of absorber on a high surface area electrode and, consequently, be used as a further special embodiment of the photovoltaic layer in accordance with the present invention.

As used herein, the term “evaluation device” generally refers to an arbitrary device designed to generate the items of information, i.e. the at least one item of information on the position of the object, in particular on the lateral position of the object. As an example, the evaluation device may be or may comprise one or more integrated circuits, such as one or more application-specific integrated circuits (ASICs), and/or one or more data processing devices, such as one or more computers, preferably one or more microcomputers and/or microcontrollers. Additional components may be comprised, such as one or more preprocessing devices and/or data acquisition devices, such as one or more devices for receiving and/or preprocessing of the sensor signals, such as one or more AD-converters and/or one or more filters. As used herein, the sensor signal may generally refer to one of the transversal sensor signals and, if applicable, to the longitudinal sensor signal. Further, the evaluation device may comprise one or more data storage devices. Further, as outlined above, the evaluation device may comprise one or more interfaces, such as one or more wireless interfaces and/or one or more wire-bound interfaces.

The at least one evaluation device may be adapted to perform at least one computer program, such as at least one computer program performing or supporting the step of generating the items of information. As an example, one or more algorithms may be implemented which, by using the sensor signals as input variables, may perform a predetermined transformation into the position of the object.

The evaluation device may particularly comprise at least one data processing device, in particular an electronic data processing device, which can be designed to generate the items of information by evaluating the sensor signals. Thus, the evaluation device is designed to use the sensor signals as input variables and to generate the items of information on the transversal position and, if applicable, the longitudinal position of the object by processing these input variables. The processing can be done in parallel, subsequently or even in a combined manner. The evaluation device may use an arbitrary process for generating these items of information, such as by calculation and/or using at least one stored and/or known relationship. Besides the sensor signals, one or a plurality of further parameters and/or items of information can influence said relationship, for example at least one item of information about a modulation frequency. The relationship can be determined or determinable empirically, analytically or else semi-empirically. Particularly preferably, the relationship comprises at least one calibration curve, at least one set of calibration curves, at least one function or a combination of the possibilities mentioned. One or a plurality of calibration curves can be stored for example in the form of a set of values and the associated function values thereof, for example in a data storage device and/or a table. Alternatively or additionally, however, the at least one calibration curve can also be stored for example in parameterized form and/or as a functional equation. Separate relationships for processing the sensor signals into the items of information may be used. Alternatively, at least one combined relationship for processing the sensor signals is feasible. Various possibilities are conceivable and can also be combined.

By way of example, the evaluation device can be designed in terms of programming for the purpose of determining the items of information. The evaluation device can comprise in particular at least one computer, for example at least one microcomputer. Furthermore, the evaluation device can comprise one or a plurality of volatile or nonvolatile data memories. As an alternative or in addition to a data processing device, in particular at least one computer, the evaluation device can comprise one or a plurality of further electronic components which are designed for determining the items of information, for example an electronic table and in particular at least one look-up table and/or at least one application-specific integrated circuit (ASIC).

The detector has, as described above, at least one evaluation device. In particular, the at least one evaluation device can also be designed to completely or partly control or drive the detector, for example by the evaluation device being designed to control at least one illumination source and/or to control at least one modulation device of the detector. The evaluation device can be designed, in particular, to carry out at least one measurement cycle in which one or a plurality of sensor signals, such as a plurality of sensor signals, are picked up, for example a plurality of sensor signals of successively at different modulation frequencies of the illumination.

The evaluation device is designed, as described above, to generate at least one item of information on the position of the object by evaluating the at least one sensor signal. Said position of the object can be static or may even comprise at least one movement of the object, for example a relative movement between the detector or parts thereof and the object or parts thereof. In this case, a relative movement can generally comprise at least one linear movement and/or at least one rotational movement. Items of movement information can for example also be obtained by comparison of at least two items of information picked up at different times, such that for example at least one item of location information can also comprise at least one item of velocity information and/or at least one item of acceleration information, for example at least one item of information about at least one relative velocity between the object or parts thereof and the detector or parts thereof. In particular, the at least one item of location information can generally be selected from: an item of information about a distance between the object or parts thereof and the detector or parts thereof, in particular an optical path length; an item of information about a distance or an optical distance between the object or parts thereof and the optional transfer device or parts thereof; an item of information about a positioning of the object or parts thereof relative to the detector or parts thereof; an item of information about an orientation of the object and/or parts thereof relative to the detector or parts thereof; an item of information about a relative movement between the object or parts thereof and the detector or parts thereof; an item of information about a two-dimensional or three-dimensional spatial configuration of the object or of parts thereof, in particular a geometry or form of the object. Generally, the at least one item of location information can therefore be selected for example from the group consisting of: an item of information about at least one location of the object or at least one part thereof; information about at least one orientation of the object or a part thereof; an item of information about a geometry or form of the object or of a part thereof, an item of information about a velocity of the object or of a part thereof, an item of information about an acceleration of the object or of a part thereof, an item of information about a presence or absence of the object or of a part thereof in a visual range of the detector. The at least one item of location information can be specified for example in at least one coordinate system, for example a coordinate system in which the detector or parts thereof rest. Alternatively or additionally, the location information can also simply comprise for example a distance between the detector or parts thereof and the object or parts thereof. Combinations of the possibilities mentioned are also conceivable.

Herein, some of the mentioned information may be determined by using only at least one lateral detector optical sensor according to the present invention whereas acquiring other information may require, additionally, at least one longitudinal optical sensor. Thus, as used herein, the term “longitudinal optical sensor” may, generally, refer to a device which is designed to generate at least one longitudinal sensor signal in a manner dependent on an illumination of the sensor region by the light beam, wherein the longitudinal sensor signal, given the same total power of the illumination, is dependent, according to the so-called “FiP effect” on a beam cross-section of the light beam in the sensor region. The longitudinal sensor signal may generally be an arbitrary signal indicative of the longitudinal position, which may also be denoted as a depth.

In a particularly preferred embodiment, the transversal optical sensor according to the present invention may concurrently be employed as the longitudinal optical sensor. As described in a particular embodiment of PCT patent application No. PCT/EP2016/051817, filed Jan. 28, 2016, the sensor region of the longitudinal optical sensor may comprise at least one photoconductive material, wherein the photoconductive material may be provided in form of a colloidal film, wherein the colloidal film may comprise quantum dots, thus allowing the concurrent use of the transversal optical sensor according to the present invention, wherein the quantum dots may comprise a photoconductive material, as the longitudinal optical sensor.

For further potential embodiments of the longitudinal optical sensor and the longitudinal sensor signal, reference may be made to the optical sensor as disclosed in WO 2012/110924 A1 or to further embodiments of the longitudinal optical sensor as described in PCT patent application No. PCT/EP2016/051817, filed Jan. 28, 2016.

As disclosed in WO 2014/097181 A1, the detector according to the present invention may comprise more than one optical sensor, in particular, one or more transversal optical sensors in combination with one or more longitudinal optical sensors, in particular, a stack of longitudinal optical sensors. As an example, one or more transversal optical sensors may be located on a side of the stack of longitudinal optical sensors facing towards the object. Alternatively or additionally, one or more transversal optical sensors may be located on a side of the stack of longitudinal optical sensors facing away from the object. Again, additionally or alternatively, one or more transversal optical sensors may be interposed in between the longitudinal optical sensors of the stack. However, embodiments which may only comprise a single transversal optical sensor but no longitudinal optical sensor may still be possible, such as in a case wherein only determining one or more lateral dimensions of the object may be desired.

Accordingly, the detector may comprise at least two optical sensors, wherein each optical sensor may be adapted to generate at least one sensor signal. As an example, the sensor surfaces of the optical sensors may, thus, be oriented in parallel, wherein slight angular tolerances might be tolerable, such as angular tolerances of no more than 10°, preferably of no more than 5°. Herein, preferably all of the optical sensors of the detector, which may, preferably, be arranged in form of a stack along the optical axis of the detector, may be transparent. Thus, the light beam may pass through a first transparent optical sensor before impinging on the other optical sensors, preferably subsequently. Thus, the light beam from the object may subsequently reach all optical sensors present in the optical detector. For this purpose, the last optical sensor, i.e. the optical sensor which is finally impinged by the incident light beam, may also be intransparent. Herein, the different optical sensors may exhibit the same or different spectral sensitivities with respect to the incident light beam.

Further embodiments of the present invention may refer to the nature of the light beam which may propagate from the object to the detector. As used herein, the term “light” generally refers to electromagnetic radiation in one or more of the visible spectral range, the ultraviolet spectral range and the infrared spectral range. Therein, in partial accordance with standard ISO-21348 in a valid version at the date of this application, the term visible spectral range generally refers to a spectral range of 380 nm to 760 nm. The term infrared (IR) spectral range generally refers to electromagnetic radiation in the range of 760 nm to 1000 μm, wherein the range of 760 nm to 1.4 μm is usually denominated as the near infrared (NIR) spectral range, and the range from 15 μm to 1000 μm as the far infrared (FIR) spectral range. The term ultraviolet spectral range generally refers to electromagnetic radiation in the range of 1 nm to 380 nm, preferably in the range of 100 nm to 380 nm. Preferably, light as used within the present invention is visible light, i.e. light in the visible spectral range.

The term “light beam” generally refers to an amount of light emitted into a specific direction.

Thus, the light beam may be a bundle of the light rays having a predetermined extension in a direction perpendicular to a direction of propagation of the light beam. Preferably, the light beam may be or may comprise one or more Gaussian light beams which may be characterized by one or more Gaussian beam parameters, such as one or more of a beam waist, a Rayleigh-length or any other beam parameter or combination of beam parameters suited to characterize a development of a beam diameter and/or a beam propagation in space.

The light beam might be admitted by the object itself, i.e. might originate from the object. Additionally or alternatively, another origin of the light beam is feasible. Thus, as will be outlined in further detail below, one or more illumination sources might be provided which illuminate the object, such as by using one or more primary rays or beams, such as one or more primary rays or beams having a predetermined characteristic. In the latter case, the light beam propagating from the object to the detector might be a light beam which is reflected by the object and/or a reflection device connected to the object.

In addition, the detector may comprise at least one transfer device, such as an optical lens, in particular one or more refractive lenses, particularly converging thin refractive lenses, such as convex or biconvex thin lenses, and/or one or more convex mirrors, which may further be arranged along the common optical axis. Most preferably, the light beam which emerges from the object may in this case travel first through the at least one transfer device and thereafter through the at least one transparent transversal optical sensor until it may finally impinge on an imaging device. As used herein, the term “transfer device” refers to an optical element which may be configured to transfer the at least one light beam emerging from the object to optical sensors within the detector, i.e. the at least one transversal optical sensor and the at least one optional longitudinal optical sensor. Thus, the transfer device can be designed to feed light propagating from the object to the detector to the optical sensors, wherein this feeding can optionally be effected by means of imaging or else by means of non-imaging properties of the transfer device. In particular the transfer device can also be designed to collect the electromagnetic radiation before the latter is fed to the transversal optical sensor and/or, if applicable, to the optional longitudinal optical sensor.

In addition, the at least one transfer device may have imaging properties. Consequently, the transfer device comprises at least one imaging element, for example at least one lens and/or at least one curved mirror, since, in the case of such imaging elements, for example, a geometry of the illumination on the sensor region can be dependent on a relative positioning, for example a distance, between the transfer device and the object. As used herein, the transfer device may be designed in such a way that the electromagnetic radiation which emerges from the object is transferred completely to the sensor region, for example is focused completely onto the optical sensor, in particular if the object is arranged in a visual range of the detector.

Generally, the detector may further comprise at least one imaging device, i.e. a device capable of acquiring at least one image. The imaging device can be embodied in various ways. Thus, the imaging device can be for example part of the detector in a detector housing. Alternatively or additionally, however, the imaging device can also be arranged outside the detector housing, for example as a separate imaging device. Alternatively or additionally, the imaging device can also be connected to the detector or even be part of the detector. In a preferred arrangement, the at least one optical sensor and the imaging device are aligned along a common optical axis along which the light beam travels. Thus, it may be possible to locate an imaging device in the optical path of the light beam in a manner that the light beam travels through the at least one optical sensor until it impinges on the imaging device. However, other arrangements are possible.

As used herein, an “imaging device” is generally understood as a device which can generate a one-dimensional, a two-dimensional, or a three-dimensional image of the object or of a part thereof. In particular, the detector, with or without the at least one optional imaging device, can be completely or partly used as a camera, such as an IR camera, or an RGB camera, i.e. a camera which is designed to deliver three basic colors which are designated as red, green, and blue, on three separate connections. Thus, as an example, the at least one imaging device may be or may comprise at least one imaging device selected from the group consisting of: a pixelated organic camera element, preferably a pixelated organic camera chip; a pixelated inorganic camera element, preferably a pixelated inorganic camera chip, more preferably a CCD- or CMOS-chip; a monochrome camera element, preferably a monochrome camera chip; a multicolor camera element, preferably a multicolor camera chip; a full-color camera element, preferably a full-color camera chip. The imaging device may be or may comprise at least one device selected from the group consisting of a monochrome imaging device, a multi-chrome imaging device and at least one full color imaging device. A multi-chrome imaging device and/or a full color imaging device may be generated by using filter techniques and/or by using intrinsic color sensitivity or other techniques, as the skilled person will recognize. Other embodiments of the imaging device are also possible.

The imaging device may be designed to image a plurality of partial regions of the object successively and/or simultaneously. By way of example, a partial region of the object can be a one-dimensional, a two-dimensional, or a three-dimensional region of the object which is delimited for example by a resolution limit of the imaging device and from which electromagnetic radiation emerges. In this context, imaging should be understood to mean that the electromagnetic radiation which emerges from the respective partial region of the object is fed into the imaging device, for example by means of the at least one optional transfer device of the detector. The electromagnetic rays can be generated by the object itself, for example in the form of a luminescent radiation. Alternatively or additionally, the at least one detector may comprise at least one illumination source for illuminating the object.

In particular, the imaging device can be designed to image sequentially, for example by means of a scanning method, in particular using at least one row scan and/or line scan, the plurality of partial regions sequentially. However, other embodiments are also possible, for example embodiments in which a plurality of partial regions is simultaneously imaged. The imaging device is designed to generate, during this imaging of the partial regions of the object, signals, preferably electronic signals, associated with the partial regions. The signal may be an analogue and/or a digital signal. By way of example, an electronic signal can be associated with each partial region. The electronic signals can accordingly be generated simultaneously or else in a temporally staggered manner. By way of example, during a row scan or line scan, it is possible to generate a sequence of electronic signals which correspond to the partial regions of the object, which are strung together in a line, for example. Further, the imaging device may comprise one or more signal processing devices, such as one or more filters and/or analogue-digital-converters for processing and/or preprocessing the electronic signals.

Light emerging from the object can originate in the object itself, but can also optionally have a different origin and propagate from this origin to the object and subsequently toward the optical sensors. The latter case can be affected for example by at least one illumination source being used. The illumination source can be embodied in various ways. Thus, the illumination source can be for example part of the detector in a detector housing. Alternatively or additionally, however, the at least one illumination source can also be arranged outside a detector housing, for example as a separate light source. The illumination source can be arranged separately from the object and illuminate the object from a distance. Alternatively or additionally, the illumination source can also be connected to the object or even be part of the object, such that, by way of example, the electromagnetic radiation emerging from the object can also be generated directly by the illumination source. By way of example, at least one illumination source can be arranged on and/or in the object and directly generate the electromagnetic radiation by means of which the sensor region is illuminated. This illumination source can for example be or comprise an ambient light source and/or may be or may comprise an artificial illumination source. By way of example, at least one infrared emitter and/or at least one emitter for visible light and/or at least one emitter for ultraviolet light can be arranged on the object. By way of example, at least one light emitting diode and/or at least one laser diode can be arranged on and/or in the object. The illumination source can comprise in particular one or a plurality of the following illumination sources: a laser, in particular a laser diode, although in principle, alternatively or additionally, other types of lasers can also be used; a light emitting diode; an incandescent lamp; a neon light; a flame source; a heat source; an organic light source, in particular an organic light emitting diode; a structured light source. Alternatively or additionally, other illumination sources can also be used. It is particularly preferred if the illumination source is designed to generate one or more light beams having a Gaussian beam profile, as is at least approximately the case for example in many lasers. For further potential embodiments of the optional illumination source, reference may be made to one of WO 2012/110924 A1 and WO 2014/097181 A1. Still, other embodiments are feasible.

The at least one optional illumination source generally may emit light in at least one of: the ultraviolet spectral range, preferably in the range of 200 nm to 380 nm; the visible spectral range (380 nm to 780 nm); the infrared spectral range, preferably in the range of 780 nm to 3.0 micrometers. Most preferably, the at least one illumination source is adapted to emit light in the infrared (IR) spectral range, preferably in the near-infrared (NIR) spectral range from 780 nm to 1.5 micrometers. Herein, it is particularly preferred when the illumination source may exhibit a spectral range which may be related to the spectral sensitivities of the transversal sensors, particularly in a manner to ensure that the transversal sensor which may be illuminated by the respective illumination source may provide a sensor signal with a high intensity which may, thus, enable a high-resolution evaluation with a sufficient signal-to-noise-ratio.

Irrespective of the actual configuration of this preferred embodiment, a comparatively simple and cost-efficient setup for the transversal optical sensor may be obtained, wherein the transversal optical sensor may comprise at least partially transparent optical properties and may, in addition, exhibit a comparatively high sensitivity within the infrared (IR) spectral range, preferably within the near-infrared (NIR) spectral range. Thus, the setup for the transversal optical sensor according to the present invention may, in particular, allow using this kind of transversal optical sensor as a position sensitive device. However, other embodiments may also be appropriate.

Furthermore, the detector can have at least one modulation device for modulating the illumination, in particular for a periodic modulation, in particular a periodic beam interrupting device. A modulation of the illumination should be understood to mean a process in which a total power of the illumination is varied, preferably periodically, in particular with one or a plurality of modulation frequencies. In particular, a periodic modulation can be effected between a maximum value and a minimum value of the total power of the illumination. The minimum value can be 0, but can also be >0, such that, by way of example, complete modulation does not have to be effected. The modulation can be effected for example in a beam path between the object and the optical sensor, for example by the at least one modulation device being arranged in said beam path. Alternatively or additionally, however, the modulation can also be effected in a beam path between an optional illumination source—described in even greater detail below—for illuminating the object and the object, for example by the at least one modulation device being arranged in said beam path. A combination of these possibilities is also conceivable. The at least one modulation device can comprise for example a beam chopper or some other type of periodic beam interrupting device, for example comprising at least one interrupter blade or interrupter wheel, which preferably rotates at constant speed and which can thus periodically interrupt the illumination. Alternatively or additionally, however, it is also possible to use one or a plurality of different types of modulation devices, for example modulation devices based on an electro-optical effect and/or an acousto-optical effect. Once again alternatively or additionally, the at least one optional illumination source itself can also be designed to generate a modulated illumination, for example by said illumination source itself having a modulated intensity and/or total power, for example a periodically modulated total power, and/or by said illumination source being embodied as a pulsed illumination source, for example as a pulsed laser. Thus, by way of example, the at least one modulation device can also be wholly or partly integrated into the illumination source. Various possibilities are conceivable.

Accordingly, the detector can be designed in particular to detect at least two transversal sensor signals in the case of different modulations, in particular at least two transversal sensor signals at respectively different modulation frequencies. As a result, the two different transversal sensor signals may, thus, be distinguishable, by their respectively different modulation frequencies. The evaluation device can be designed to generate the geometrical information from the at least two transversal sensor signals. By way of example, the detector can be designed to bring about a modulation of the illumination of the object and/or at least the transversal optical sensor with a frequency of 0.05 Hz to 1 MHz, such as 0.1 Hz to 10 kHz. As outlined above, for this purpose, the detector may comprise at least one modulation device, which may be integrated into the at least one optional illumination source and/or may be independent from the illumination source. Thus, at least one illumination source might, by itself, be adapted to generate the above-mentioned modulation of the illumination, and/or at least one independent modulation device may be present, such as at least one chopper and/or at least one device having a modulated transmissibility, such as at least one electro-optical device and/or at least one acousto-optical device.

In a further aspect of the present invention, a human-machine interface for exchanging at least one item of information between a user and a machine is proposed. The human-machine interface as proposed may make use of the fact that the above-mentioned detector in one or more of the embodiments mentioned above or as mentioned in further detail below may be used by one or more users for providing information and/or commands to a machine. Thus, preferably, the human-machine interface may be used for inputting control commands.

The human-machine interface comprises at least one detector according to the present invention, such as according to one or more of the embodiments disclosed above and/or according to one or more of the embodiments as disclosed in further detail below, wherein the human-machine interface is designed to generate at least one item of geometrical information of the user by means of the detector wherein the human-machine interface is designed to assign the geometrical information to at least one item of information, in particular to at least one control command.

In a further aspect of the present invention, an entertainment device for carrying out at least one entertainment function is disclosed. As used herein, an entertainment device is a device which may serve the purpose of leisure and/or entertainment of one or more users, in the following also referred to as one or more players. As an example, the entertainment device may serve the purpose of gaming, preferably computer gaming. Additionally or alternatively, the entertainment device may also be used for other purposes, such as for exercising, sports, physical therapy or motion tracking in general. Thus, the entertainment device may be implemented into a computer, a computer network or a computer system or may comprise a computer, a computer network or a computer system which runs one or more gaming software programs.

The entertainment device comprises at least one human-machine interface according to the present invention, such as according to one or more of the embodiments disclosed above and/or according to one or more of the embodiments disclosed below. The entertainment device is designed to enable at least one item of information to be input by a player by means of the human-machine interface. The at least one item of information may be transmitted to and/or may be used by a controller and/or a computer of the entertainment device.

In a further aspect of the present invention, a tracking system for tracking the position of at least one movable object is provided. As used herein, a tracking system is a device which is adapted to gather information on a series of past positions of the at least one object or at least one part of an object. Additionally, the tracking system may be adapted to provide information on at least one predicted future position of the at least one object or the at least one part of the object. The tracking system may have at least one track controller, which may fully or partially be embodied as an electronic device, preferably as at least one data processing device, more preferably as at least one computer or microcontroller. Again, the at least one track controller may comprise the at least one evaluation device and/or may be part of the at least one evaluation device and/or might fully or partially be identical to the at least one evaluation device.

The tracking system comprises at least one detector according to the present invention, such as at least one detector as disclosed in one or more of the embodiments listed above and/or as disclosed in one or more of the embodiments below. The tracking system further comprises at least one track controller. The tracking system may comprise one, two or more detectors, particularly two or more identical detectors, which allow for a reliable acquisition of depth information about the at least one object in an overlapping volume between the two or more detectors. The track controller is adapted to track a series of positions of the object, each position comprising at least one item of information on a position of the object at a specific point in time.

The tracking system may further comprise at least one beacon device connectable to the object. For a potential definition of the beacon device, reference may be made to WO 2014/097181 A1. The tracking system preferably is adapted such that the detector may generate an information on the position of the object of the at least one beacon device, in particular to generate the information on the position of the object which comprises a specific beacon device exhibiting a specific spectral sensitivity. Thus, more than one beacon exhibiting a different spectral sensitivity may be tracked by the detector of the present invention, preferably in a simultaneous manner. Herein, the beacon device may fully or partially be embodied as an active beacon device and/or as a passive beacon device. As an example, the beacon device may comprise at least one illumination source adapted to generate at least one light beam to be transmitted to the detector. Additionally or alternatively, the beacon device may comprise at least one reflector adapted to reflect light generated by an illumination source, thereby generating a reflected light beam to be transmitted to the detector.

In a further aspect of the present invention, a scanning system for determining at least one position of at least one object is provided. As used herein, the scanning system is a device which is adapted to emit at least one light beam being configured for an illumination of at least one dot located at least one surface of the at least one object and for generating at least one item of information about the distance between the at least one dot and the scanning system. For the purpose of generating the at least one item of information about the distance between the at least one dot and the scanning system, the scanning system comprises at least one of the detectors according to the present invention, such as at least one of the detectors as disclosed in one or more of the embodiments listed above and/or as disclosed in one or more of the embodiments below.

Thus, the scanning system comprises at least one illumination source which is adapted to emit the at least one light beam being configured for the illumination of the at least one dot located at the at least one surface of the at least one object. As used herein, the term “dot” refers to a small area on a part of the surface of the object which may be selected, for example by a user of the scanning system, to be illuminated by the illumination source. Preferably, the dot may exhibit a size which may, on one hand, be as small as possible in order to allow the scanning system determining a value for the distance between the illumination source comprised by the scanning system and the part of the surface of the object on which the dot may be located as exactly as possible and which, on the other hand, may be as large as possible in order to allow the user of the scanning system or the scanning system itself, in particular by an automatic procedure, to detect a presence of the dot on the related part of the surface of the object.

For this purpose, the illumination source may comprise an artificial illumination source, in particular at least one laser source and/or at least one incandescent lamp and/or at least one semiconductor light source, for example, at least one light-emitting diode, in particular an organic and/or inorganic light-emitting diode. On account of their generally defined beam profiles and other properties of handleability, the use of at least one laser source as the illumination source is particularly preferred. Herein, the use of a single laser source may be preferred, in particular in a case in which it may be important to provide a compact scanning system that might be easily storable and transportable by the user. The illumination source may thus, preferably be a constituent part of the detector and may, therefore, in particular be integrated into the detector, such as into the housing of the detector. In a preferred embodiment, particularly the housing of the scanning system may comprise at least one display configured for providing distance-related information to the user, such as in an easy-to-read manner. In a further preferred embodiment, particularly the housing of the scanning system may, in addition, comprise at least one button which may be configured for operating at least one function related to the scanning system, such as for setting one or more operation modes. In a further preferred embodiment, particularly the housing of the scanning system may, in addition, comprise at least one fastening unit which may be configured for fastening the scanning system to a further surface, such as a rubber foot, a base plate or a wall holder, such comprising as magnetic material, in particular for increasing the accuracy of the distance measurement and/or the handleablity of the scanning system by the user.

In a particularly preferred embodiment, the illumination source of the scanning system may, thus, emit a single laser beam which may be configured for the illumination of a single dot located at the surface of the object. By using at least one of the detectors according to the present invention at least one item of information about the distance between the at least one dot and the scanning system may, thus, be generated. Hereby, preferably, the distance between the illumination system as comprised by the scanning system and the single dot as generated by the illumination source may be determined, such as by employing the evaluation device as comprised by the at least one detector. However, the scanning system may, further, comprise an additional evaluation system which may, particularly, be adapted for this purpose. Alternatively or in addition, a size of the scanning system, in particular of the housing of the scanning system, may be taken into account and, thus, the distance between a specific point on the housing of the scanning system, such as a front edge or a back edge of the housing, and the single dot may, alternatively, be determined.

Alternatively, the illumination source of the scanning system may emit two individual laser beams which may be configured for providing a respective angle, such as a right angle, between the directions of an emission of the beams, whereby two respective dots located at the surface of the same object or at two different surfaces at two separate objects may be illuminated. However, other values for the respective angle between the two individual laser beams may also be feasible. This feature may, in particular, be employed for indirect measuring functions, such as for deriving an indirect distance which may not be directly accessible, such as due to a presence of one or more obstacles between the scanning system and the dot or which may otherwise be hard to reach. By way of example, it may, thus, be feasible to determine a value for a height of an object by measuring two individual distances and deriving the height by using the Pythagoras formula. In particular for being able to keep a predefined level with respect to the object, the scanning system may, further, comprise at least one leveling unit, in particular an integrated bubble vial, which may be used for keeping the predefined level by the user.

As a further alternative, the illumination source of the scanning system may emit a plurality of individual laser beams, such as an array of laser beams which may exhibit a respective pitch, in particular a regular pitch, with respect to each other and which may be arranged in a manner in order to generate an array of dots located on the at least one surface of the at least one object. For this purpose, specially adapted optical elements, such as beam-splitting devices and mirrors, may be provided which may allow a generation of the described array of the laser beams.

Thus, the scanning system may provide a static arrangement of the one or more dots placed on the one or more surfaces of the one or more objects. Alternatively, illumination source of the scanning system, in particular the one or more laser beams, such as the above described array of the laser beams, may be configured for providing one or more light beams which may exhibit a varying intensity over time and/or which may be subject to an alternating direction of emission in a passage of time. Thus, the illumination source may be configured for scanning a part of the at least one surface of the at least one object as an image by using one or more light beams with alternating features as generated by the at least one illumination source of the scanning device. In particular, the scanning system may, thus, use at least one row scan and/or line scan, such as to scan the one or more surfaces of the one or more objects sequentially or simultaneously.

In a further aspect of the present invention, a camera for imaging at least one object is disclosed. The camera comprises at least one detector according to the present invention, such as disclosed in one or more of the embodiments given above or given in further detail below. In a particularly preferred embodiment, the camera may comprise at least one transversal optical detector according to the present invention together with at least one longitudinal optical sensor, such as described in WO 2012/110924 A1, WO 2014/097181 A1, or in PCT patent application No. PCT/EP2016/051817, filed Jan. 28, 2016. Thus, the detector may be part of a photographic device, specifically of a digital camera. Specifically, the detector may be used in 3D photography, specifically in digital 3D photography. Thus, the detector may be part of a digital 3D camera. As used herein, the term “photography” generally refers to the technology of acquiring image information of at least one object. As further used herein, a “camera” generally is a device adapted for performing photography. As further used herein, the term “digital photography” generally refers to the technology of acquiring image information of at least one object by using a plurality of light-sensitive elements adapted to generate electrical signals indicating an intensity of illumination, preferably digital electrical signals. As further used herein, the term “3D photography” generally refers to the technology of acquiring image information of at least one object in three spatial dimensions. Accordingly, a 3D camera is a device adapted for performing 3D photography. The camera generally may be adapted for acquiring a single image, such as a single 3D image, or may be adapted for acquiring a plurality of images, such as a sequence of images. Thus, the camera may also be a video camera adapted for video applications, such as for acquiring digital video sequences.

Thus, generally, the present invention further refers to a camera, specifically a digital camera, more specifically a 3D camera or digital 3D camera, for imaging at least one object. As outlined above, the term “imaging”, as used herein, generally refers to acquiring image information of at least one object. The camera comprises at least one detector according to the present invention. The camera, as outlined above, may be adapted for acquiring a single image or for acquiring a plurality of images, such as image sequence, preferably for acquiring digital video sequences. Thus, as an example, the camera may be or may comprise a video camera. In the latter case, the camera preferably comprises a data memory for storing the image sequence.

In a further aspect of the present invention, a method for determining a position of at least one object is disclosed. The method preferably may make use of at least one detector according to the present invention, such as of at least one detector according to one or more of the embodiments disclosed above or disclosed in further detail below. Thus, for optional embodiments of the method, reference might be made to the description of the various embodiments of the detector.

The method comprises the following steps, which may be performed in the given order or in a different order. Further, additional method steps might be provided which are not listed. Further, two or more or even all of the method steps might be performed simultaneously, at least partially. Further, two or more or even all of the method steps might be performed twice or even more than twice, repeatedly.

The method according to the present invention comprises the following steps:
generating at least one transversal sensor signal by using at least one transversal optical sensor, the transversal optical sensor being adapted to determine a transversal position of a light beam traveling from the object to the detector, wherein the transversal position is a position in at least one dimension perpendicular to an optical axis of the detector, wherein the transversal optical sensor has at least one photovoltaic layer embedded between at least two conductive layers, wherein the photovoltaic layer comprises a plurality of quantum dots, wherein at least one of the conductive layers is at least partially transparent allowing the light beam to travel to the photovoltaic layer, wherein the transversal optical sensor further has at least one split electrode located at one of the conductive layers, wherein the split electrode has at least two partial electrodes adapted to generate at least one transversal sensor signal, wherein the at least one transversal sensor signal indicates the transversal position of the light beam in the photovoltaic layer; and
generating at least one item of information on a transversal position of the object by evaluating the at least one transversal sensor signal.

As described above, the photovoltaic layer material may, in a preferred embodiment, be obtained by providing a thin film comprising colloidal quantum dots (CQD). Herein, the CQD film may, preferably, be deposited onto a conductive layer, wherein first conductive layer may comprise an at least partially transparent semiconducting material which may, preferably, be selected from the group comprising an at least partially transparent semiconducting metal oxide or a doped variant thereof, in particular selected from indium tin oxide (ITO), fluorine-doped tin oxide (SnO2:F; FTO), aluminum zinc oxide (AZO), antimony tin oxide (SnO_{2/}Sb₂O₅), zinc oxide (ZnO), or a perovskite TCO, such as SrVO₃, or CaVO₃, or, alternatively, from metal nanowires, such as Ag or Cu nanowires,. Herein, the CQD film may be provided as a solution of the quantum dots in an nonpolar organic solvent, wherein the solvent may, preferably, be selected from the group comprising octane, toluene, cyclohexane, n-heptane, benzene, chlorobenzene, acetonitrile, dimethylformamide (DMF), and chloroform. Preferably, the quantum dots may be provided in a concentration from 10 mg/ml to 200 mg/ml, preferably from 50 mg/ml to 100 mg/ml, in the organic solvent.

Generally, the CQD film may be provided as a single layer or as at least two separately processed layers, preferably as exactly two separate layers. However, three, four, five, or six separately processed layers may also be feasible. Irrespective whether a single layer or multiple layers may be processed, the CQD film may, preferably be provided by a deposition method, preferably by a coating method, more preferred by a spin-coating or slot coating; by ink-jet printing; or by a blade coating method. Preferably, the CQD film may undergo a treatment with an organic agent, wherein the organic agent may, preferably, be selected from the group comprising thioles and amines, in particular from butylamine, 1,2-ethanedithiol (edt), 1,2- and 1,3-benzenedithiol (bdt), and or oleic acid. By way of example, for treatment of a colloidal film which comprises lead sulfide quantum dots (PbS CQD), the organic agent butylamine has successfully been employed. After the treatment with the organic agent, the CQD film may, preferably, be dried at a temperature from 50° C. to 250° C., preferably from 80° C. to 220° C., more preferred from 100° C. to 200° C. at air. As further described above, an n-type material layer might, firstly, be deposited in a direct manner onto the first conductive layer before the CQD film may be deposited onto the blocking layer. Herein, the blocking layer may comprise a thin film of an electrically conducting material, preferably titanium dioxide (TiO₂) or zinc oxide (ZnO).

As further described above, a further conductive layer may, additionally, be deposited onto the single or multiple CQD film, wherein the further conductive layer may comprise an at least partially transparent semiconducting material or, preferably, an intransparent electrically conducting material, more preferred an evaporated metal layer, in particular one or more of silver, aluminum, platinum, chromium, titanium, or gold.

Alternatively, the further conductive layer may comprise a layer of an electrically conducting polymer, in particular, poly(3,4-ethylenedioxythiophene) (PEDOT) or a dispersion of PEDOT and a polystyrene sulfonic acid (PEDOT:PSS). Further, a split electrode comprising evaporated metal contacts is, additionally, arranged on top of the layer of the electrically conducting polymer, wherein the evaporated metal contacts may, in particular, comprise one or more of silver, aluminum, platinum, titanium, chromium, or gold.

For further details concerning the method according to the present invention, reference may be made to the description of the optical detector as provided above and/or below.

In a further aspect of the present invention, a use of a detector according to the present invention is disclosed. Therein, a use of the detector for a purpose of determining a position of an object, in particular a lateral position of an object, is proposed, wherein the detector may, preferably, be used concurrently as at least one longitudinal optical sensor or combined with at least one additional longitudinal optical sensor, in particular, for a purpose of use selected from the group consisting of: a position measurement, in particular in traffic technology; an entertainment application; a security application; a human-machine interface application; a tracking application; a scanning application; a stereoscopic vision application; a photography application; an imaging application or camera application; a mapping application for generating maps of at least one space; a homing or tracking beacon detector for vehicles; a position measurement of objects with a thermal signature (hotter or colder than background); a machine vision application; a robotic application.

Specifically, the detector according to the present invention may, particularly depending on the material selected for the quantum dots within the photovoltaic layer, be used as an optical detector for electromagnetic waves over a considerably wide spectral range. Within this regard, the ultraviolet (UV), visible, near infrared (NIR), and the infrared (IR) spectral range may particularly be preferred. As non-limiting examples, the following materials may, particularly, be selected for the quantum dots:
for the UV spectral range gallium nitride (GaN) or gallium phosphide (GaP);
for the visible spectral range cadmium sulfide (CdS), cadmium telluride (CdTe), copper indium sulfide (CuInS₂; CIS), copper indium gallium selenide (CIGS), copper zinc tin sulfide (CZTS), quantum dots comprising lead sulfide (PbS), or indium phosphide (InP);
or the NIR spectral range cadmium telluride (CdTe), copper indium sulfide (CuInS₂; CIS), copper indium gallium selenide (CIGS), or copper zinc tin sulfide (CZTS), in particular for wavelengths above 850 nm; and
for IR spectral range indium allium arsenide (InGaAs) for wavelengths up to 2.6 μm; indium arsenide (InAs) for wavelengths up to 3.1 μm; lead sulfide (PbS) for wavelengths up to 3.5 μm; lead selenide (PbSe) for wavelengths up to 5 μm; indium antimony (InSb) for wavelengths up to 5.5 μm; and mercury cadmium telluride (MCT, HgCdTe) for wavelengths up 16 μm.

In this regard, it may particularly be emphasized that many of the mentioned materials are well known as cost-efficient, long-term stable and reliable materials which have been developed over many years, especially for optimized sensing, particularly for the indicated spectral ranges. It may, therefore, be considered as a particular advantage of the present invention to be able to adapt commercially already available materials for the extended purposes as proposed by the present invention.

Further uses of the optical detector according to the present invention may also refer to combinations with applications already been known, such as determining the presence or absence of an object; extending optical applications, e.g. camera exposure control, auto slide focus, automated rear view mirrors, electronic scales, automatic gain control, particularly in modulated light sources, automatic headlight dimmers, night (street) light controls, oil burner flame outs, or smoke detectors; or other applications, such as in densitometers, e.g. determining the density of toner in photocopy machines; or in colorimetric measurements.

Thus, generally, the devices according to the present invention, such as the detector, may be applied in various fields of uses. Specifically, the detector may be applied for a purpose of use, selected from the group consisting of: a position measurement in traffic technology; an entertainment application; a security application; a human-machine interface application; a tracking application; a photography application; a cartography application; a mapping application for generating maps of at least one space; a homing or tracking beacon detector for vehicles; a mobile application; a webcam; an audio device; a Dolby surround audio system; a computer peripheral device; a gaming application; a camera or video application; a surveillance application; an automotive application; a transport application; a logistics application; a vehicle application; an airplane application; a ship application; a spacecraft application; a robotic application; a medical application; a sports' application; a building application; a construction application; a manufacturing application; a machine vision application; a use in combination with at least one sensing technology selected from time-of-flight detector, radar, Lidar, ultrasonic sensors, or interferometry. Additionally or alternatively, applications in local and/or global positioning systems may be named, especially landmark-based positioning and/or navigation, specifically for use in cars or other vehicles (such as trains, motorcycles, bicycles, trucks for cargo transportation), robots or for use by pedestrians. Further, indoor positioning systems may be named as potential applications, such as for household applications and/or for robots used in manufacturing, logistics, surveillance, or maintenance technology.

Thus, firstly, the devices according to the present invention may be used in mobile phones, tablet computers, laptops, smart panels or other stationary or mobile or wearable computer or communication applications. Thus, the devices according to the present invention may be combined with at least one active light source, such as a light source emitting light in the visible range or infrared spectral range, in order to enhance performance. Thus, as an example, the devices according to the present invention may be used as cameras and/or sensors, such as in combination with mobile software for scanning and/or detecting environment, objects and living beings. The devices according to the present invention may even be combined with 2D cameras, such as conventional cameras, in order to increase imaging effects. The devices according to the present invention may further be used for surveillance and/or for recording purposes or as input devices to control mobile devices, especially in combination with voice and/or gesture recognition. Thus, specifically, the devices according to the present invention acting as human-machine interfaces, also referred to as input devices, may be used in mobile applications, such as for controlling other electronic devices or components via the mobile device, such as the mobile phone. As an example, the mobile application including at least one device according to the present invention may be used for controlling a television set, a game console, a music player or music device or other entertainment devices.

Further, the devices according to the present invention may be used in webcams or other peripheral devices for computing applications. Thus, as an example, the devices according to the present invention may be used in combination with software for imaging, recording, surveillance, scanning, or motion detection. As outlined in the context of the human-machine interface and/or the entertainment device, the devices according to the present invention are particularly useful for giving commands by facial expressions and/or body expressions. The devices according to the present invention can be combined with other input generating devices like e.g. mouse, keyboard, touchpad, microphone etc. Further, the devices according to the present invention may be used in applications for gaming, such as by using a webcam. Further, the devices according to the present invention may be used in virtual training applications and/or video conferences. Further, devices according to the present invention may be used to recognize or track hands, arms, or objects used in a virtual or augmented reality application, especially when wearing head mounted displays.

Further, the devices according to the present invention may be used in mobile audio devices, television devices and gaming devices, as partially explained above. Specifically, the devices according to the present invention may be used as controls or control devices for electronic devices, entertainment devices or the like. Further, the devices according to the present invention may be used for eye detection or eye tracking, such as in 2D- and 3D-display techniques, especially with transparent displays for augmented reality applications and/or for recognizing whether a display is being looked at and/or from which perspective a display is being looked at. Further, devices according to the present invention may be used to explore a room, boundaries, obstacles, in connection with a virtual or augmented reality application, especially when wearing a head-mounted display.

Further, the devices according to the present invention may be used in or as digital cameras such as DSC cameras and/or in or as reflex cameras such as SLR cameras. For these applications, reference may be made to the use of the devices according to the present invention in mobile applications such as mobile phones, as disclosed above.

Further, the devices according to the present invention may be used for security or surveillance applications. Thus, as an example, at least one device according to the present invention can be combined with one or more digital and/or analogue electronics that will give a signal if an object is within or outside a predetermined area (e.g. for surveillance applications in banks or museums). Specifically, the devices according to the present invention may be used for optical encryption. Detection by using at least one device according to the present invention can be combined with other detection devices to complement wavelengths, such as with IR, x-ray, UV-VIS, radar or ultrasound detectors. The devices according to the present invention may further be combined with an active infrared light source to allow detection in low light surroundings. The devices according to the present invention are generally advantageous as compared to active detector systems, specifically since the devices according to the present invention avoid actively sending signals which may be detected by third parties, as is the case e.g. in radar applications, ultrasound applications, LIDAR or similar active detector devices. Thus, generally, the devices according to the present invention may be used for an unrecognized and undetectable tracking of moving objects. Additionally, the devices according to the present invention generally are less prone to manipulations and irritations as compared to conventional devices.

Further, given the ease and accuracy of 3D detection by using the devices according to the present invention, the devices according to the present invention generally may be used for facial, body and person recognition and identification. Therein, the devices according to the present invention may be combined with other detection means for identification or personalization purposes such as passwords, finger prints, iris detection, voice recognition or other means. Thus, generally, the devices according to the present invention may be used in security devices and other personalized applications.

Further, the devices according to the present invention may be used as 3D barcode readers for product identification.

In addition to the security and surveillance applications mentioned above, the devices according to the present invention generally can be used for surveillance and monitoring of spaces and areas. Thus, the devices according to the present invention may be used for surveying and monitoring spaces and areas and, as an example, for triggering or executing alarms in case prohibited areas are violated. Thus, generally, the devices according to the present invention may be used for surveillance purposes in building surveillance or museums, optionally in combination with other types of sensors, such as in combination with motion or heat sensors, in combination with image intensifiers or image enhancement devices and/or photomultipliers. Further, the devices according to the present invention may be used in public spaces or crowded spaces to detect potentially hazardous activities such as commitment of crimes such as theft in a parking lot or unattended objects such as unattended baggage in an airport.

Further, the devices according to the present invention may advantageously be applied in camera applications such as video and camcorder applications. Thus, the devices according to the present invention may be used for motion capture and 3D-movie recording. Therein, the devices according to the present invention generally provide a large number of advantages over conventional optical devices. Thus, the devices according to the present invention generally require a lower complexity with regard to optical components. Thus, as an example, the number of lenses may be reduced as compared to conventional optical devices, such as by providing the devices according to the present invention having one lens only. Due to the reduced complexity, very compact devices are possible, such as for mobile use. Conventional optical systems having two or more lenses with high quality generally are voluminous, such as due to the general need for voluminous beam-splitters. Further, the devices according to the present invention generally may be used for focus/autofocus devices, such as autofocus cameras.

Further, the devices according to the present invention may also be used in optical microscopy, especially in confocal microscopy.

Further, the devices according to the present invention generally are applicable in the technical field of automotive technology and transport technology. Thus, as an example, the devices according to the present invention may be used as distance and surveillance sensors, such as for adaptive cruise control, emergency brake assist, lane departure warning, surround view, blind spot detection, traffic sign detection, traffic sign recognition, lane recognition, rear cross traffic alert, light source recognition for adapting the head light intensity and range depending on approaching traffic or vehicles driving ahead, adaptive front-lighting systems, automatic control of high beam head lights, adaptive cut-off lights in front light systems, glare-free high beam front lighting systems, marking animals, obstacles, or the like by headlight illumination, rear cross traffic alert, and other driver assistance systems, such as advanced driver assistance systems, or other automotive and traffic applications. Further, devices according to the present invention may be used in driver assistance systems which may, particularly, be adapted for anticipating maneuvers of the driver beforehand for collision avoidance. Further, the devices according to the present invention can also be used for velocity and/or acceleration measurements, such as by analyzing a first and second time-derivative of position information gained by using the detector according to the present invention. This feature generally may be applicable in automotive technology, transportation technology or general traffic technology. Applications in other fields of technology are feasible. A specific application in an indoor positioning system may be the detection of positioning of passengers in transportation, more specifically to electronically control the use of safety systems such as airbags. Herein, the use of an airbag may, especially, be prevented in a case in which the passenger may be located within the vehicle in a manner that a use of the airbag might cause an injury, in particular a severe injury, with the passenger. Further, in vehicles such as cars, trains, planes or the like, especially in autonomous vehicles, devices according to the present invention may be used to determine whether a driver pays attention to the traffic or is distracted, or asleep, or tired, or incapable of driving, such as due to the consumption of alcohol or other drugs.

In these or other applications, generally, the devices according to the present invention may be used as standalone devices or in combination with other sensor devices, such as in combination with radar and/or ultrasonic devices. Specifically, the devices according to the present invention may be used for autonomous driving and safety issues. Further, in these applications, the devices according to the present invention may be used in combination with infrared sensors, radar sensors, which are sonic sensors, two-dimensional cameras or other types of sensors. In these applications, the generally passive nature of the devices according to the present invention is advantageous. Thus, since the devices according to the present invention generally do not require emitting signals, the risk of interference of active sensor signals with other signal sources may be avoided. The devices according to the present invention specifically may be used in combination with recognition software, such as standard image recognition software. Thus, signals and data as provided by the devices according to the present invention typically are readily processable and, therefore, generally require lower calculation power than established stereovision systems such as LIDAR. Given the low space demand, the devices according to the present invention such as cameras may be placed at virtually any place in a vehicle, such as on or behind a window screen, on a front hood, on bumpers, on lights, on mirrors or other places and the like. Various detectors according to the present invention such as one or more detectors based on the effect disclosed within the present invention can be combined, such as in order to allow autonomously driving vehicles or in order to increase the performance of active safety concepts. Thus, various devices according to the present invention may be combined with one or more other devices according to the present invention and/or conventional sensors, such as in the windows like rear window, side window or front window, on the bumpers or on the lights.

A combination of at least one device according to the present invention such as at least one detector according to the present invention with one or more rain detection sensors is also possible. This is due to the fact that the devices according to the present invention generally are advantageous over conventional sensor techniques such as radar, specifically during heavy rain. A combination of at least one device according to the present invention with at least one conventional sensing technique such as radar may allow for a software to pick the right combination of signals according to the weather conditions.

Further, the devices according to the present invention may generally be used as break assist and/or parking assist and/or for speed measurements. Speed measurements can be integrated in the vehicle or may be used outside the vehicle, such as in order to measure the speed of other cars in traffic control. Further, the devices according to the present invention may be used for detecting free parking spaces in parking lots.

Further, the devices according to the present invention may generally be used for vision, in particular for vision under difficult visibility conditions, such as in night vision, fog vision, or fume vision. For achieving this purpose, the optical detector may comprise a specifically selected colloidal quantum dots which may be sensitive at least within a wavelength range in which small particles, such as particles being present in smoke or fume, or small droplets, such as droplets being present in fog, mist or haze, may not reflect an incident light beam or only a small partition thereof. As generally know, the reflection of the incident light beam may be small or negligent in a case in which the wavelength of the incident beam exceeds the size of the particles or of the droplets, respectively. Further, might vision may be enabled by detecting thermal radiation being emitted by a bodies and objects. Thus, the optical detector which comprises the specifically selected colloidal quantum dots which may particularly be sensitive within the infrared (IR) spectral range, preferably within the near infrared (NIR) spectral range, may, thus, allow good visibility even at night, in fume, smoke, fog, mist, or haze.

Further, the devices according to the present invention may be used in the fields of medical systems and sports. Thus, in the field of medical technology, surgery robotics, e.g. for use in endoscopes, may be named, since, as outlined above, the devices according to the present invention may require a low volume only and may be integrated into other devices. Specifically, the devices according to the present invention having one lens, at most, may be used for capturing 3D information in medical devices such as in endoscopes. Further, the devices according to the present invention may be combined with an appropriate monitoring software, in order to enable tracking and analysis of movements. This may allow an instant overlay of the position of a medical device, such as an endoscope or a scalpel, with results from medical imaging, such as obtained from magnetic resonance imaging, x-ray imaging, or ultrasound imaging. These applications are specifically valuable e.g. in medical treatments where precise location information is important such as in brain surgery and long-distance diagnosis and tele-medicine. Further, the devices according to the present invention may be used in 3D-body scanning. Body scanning may be applied in a medical context, such as in dental surgery, plastic surgery, bariatric surgery, or cosmetic plastic surgery, or it may be applied in the context of medical diagnosis such as in the diagnosis of myofascial pain syndrome, cancer, body dysmorphic disorder, or further diseases. Body scanning may further be applied in the field of sports to assess ergonomic use or fit of sports equipment.

Body scanning may further be used in the context of clothing, such as to determine a suitable size and fitting of clothes. This technology may be used in the context of tailor-made clothes or in the context of ordering clothes or shoes from the internet or at a self-service shopping device such as a micro kiosk device or customer concierge device. Body scanning in the context of clothing is especially important for scanning fully dressed customers.

Further, the devices according to the present invention may be used in the context of people counting systems, such as to count the number of people in an elevator, a train, a bus, a car, or a plane, or to count the number of people passing a hallway, a door, an aisle, a retail store, a stadium, an entertainment venue, a museum, a library, a public location, a cinema, a theater, or the like. Further, the 3D-function in the people counting system may be used to obtain or estimate further information about the people that are counted such as height, weight, age, physical fitness, or the like. This information may be used for business intelligence metrics, and/or for further optimizing the locality where people may be counted to make it more attractive or safe. In a retail environment, the devices according to the present invention in the context of people counting may be used to recognize returning customers or cross shoppers, to assess shopping behavior, to assess the percentage of visitors that make purchases, to optimize staff shifts, or to monitor the costs of a shopping mall per visitor. Further, people counting systems may be used for anthropometric surveys. Further, the devices according to the present invention may be used in public transportation systems for automatically charging passengers depending on the length of transport. Further, the devices according to the present invention may be used in playgrounds for children, to recognize injured children or children engaged in dangerous activities, to allow additional interaction with playground toys, to ensure safe use of playground toys or the like.

Further, the devices according to the present invention may be used in construction tools, such as a range meter that determines the distance to an object or to a wall, to assess whether a surface is planar, to align or objects or place objects in an ordered manner, or in inspection cameras for use in construction environments or the like.

Further, the devices according to the present invention may be applied in the field of sports and exercising, such as for training, remote instructions or competition purposes. Specifically, the devices according to the present invention may be applied in the fields of dancing, aerobic, football, soccer, basketball, baseball, cricket, hockey, track and field, swimming, polo, handball, volleyball, rugby, sumo, judo, fencing, boxing, golf, car racing, laser tag, battlefield simulation etc. The devices according to the present invention can be used to detect the position of a ball, a bat, a sword, motions, etc., both in sports and in games, such as to monitor the game, support the referee or for judgment, specifically automatic judgment, of specific situations in sports, such as for judging whether a point or a goal actually was made.

Further, the devices according to the present invention may be used in the field of auto racing or car driver training or car safety training or the like to determine the position of a car or the track of a car, or the deviation from a previous track or an ideal track or the like.

The devices according to the present invention may further be used to support a practice of musical instruments, in particular remote lessons, for example lessons of string instruments, such as fiddles, violins, violas, celli, basses, harps, guitars, banjos, or ukuleles, keyboard instruments, such as pianos, organs, keyboards, harpsichords, harmoniums, or accordions, and/or percussion instruments, such as drums, timpani, marimbas, xylophones, vibraphones, bongos, congas, timbales, djembes or tablas.

The devices according to the present invention further may be used in rehabilitation and physiotherapy, in order to encourage training and/or in order to survey and correct movements. Therein, the devices according to the present invention may also be applied for distance diagnostics.

Further, the devices according to the present invention may be applied in the field of machine vision. Thus, one or more of the devices according to the present invention may be used e.g. as a passive controlling unit for autonomous driving and or working of robots. In combination with moving robots, the devices according to the present invention may allow for autonomous movement and/or autonomous detection of failures in parts. The devices according to the present invention may also be used for manufacturing and safety surveillance, such as in order to avoid accidents including but not limited to collisions between robots, production parts and living beings. In robotics, the safe and direct interaction of humans and robots is often an issue, as robots may severely injure humans when they are not recognized. Devices according to the present invention may help robots to position objects and humans better and faster and allow a safe interaction. Given the passive nature of the devices according to the present invention, the devices according to the present invention may be advantageous over active devices and/or may be used complementary to existing solutions like radar, ultrasound, 2D cameras, IR detection etc. One particular advantage of the devices according to the present invention is the low likelihood of signal interference. Therefore multiple sensors can work at the same time in the same environment, without the risk of signal interference. Thus, the devices according to the present invention generally may be useful in highly automated production environments like e.g. but not limited to automotive, mining, steel, etc. The devices according to the present invention can also be used for quality control in production, e.g. in combination with other sensors like 2-D imaging, radar, ultrasound, IR etc., such as for quality control or other purposes. Further, the devices according to the present invention may be used for assessment of surface quality, such as for surveying the surface evenness of a product or the adherence to specified dimensions, from the range of micrometers to the range of meters. Other quality control applications are feasible. In a manufacturing environment, the devices according to the present invention are especially useful for processing natural products such as food or wood, with a complex 3-dimensional structure to avoid large amounts of waste material. Further, devices according to the present invention may be used to monitor the filling level of tanks, silos etc. Further, devices according to the present invention may be used to inspect complex products for missing parts, incomplete parts, loose parts, low quality parts, or the like, such as in automatic optical inspection, such as of printed circuit boards, inspection of assemblies or sub-assemblies, verification of engineered components, engine part inspections, wood quality inspection, label inspections, inspection of medical devices, inspection of product orientations, packaging inspections, food pack inspections, or the like.

Further, the devices according to the present invention may be used in vehicles, trains, airplanes, ships, spacecraft and other traffic applications. Thus, besides the applications mentioned above in the context of traffic applications, passive tracking systems for aircraft, vehicles and the like may be named. The use of at least one device according to the present invention, such as at least one detector according to the present invention, for monitoring the speed and/or the direction of moving objects is feasible. Specifically, the tracking of fast moving objects on land, sea and in the air including space may be named. The at least one device according to the present invention, such as the at least one detector according to the present invention, specifically may be mounted on a still-standing and/or on a moving device. An output signal of the at least one device according to the present invention can be combined e.g. with a guiding mechanism for autonomous or guided movement of another object. Thus, applications for avoiding collisions or for enabling collisions between the tracked and the steered object are feasible. The devices according to the present invention generally are useful and advantageous due to the low calculation power required, the instant response and due to the passive nature of the detection system which generally is more difficult to detect and to disturb as compared to active systems, like e.g. radar. The devices according to the present invention are particularly useful but not limited to e.g. speed control and air traffic control devices. Further, the devices according to the present invention may be used in automated tolling systems for road charges.

The devices according to the present invention may, generally, be used in passive applications. Passive applications include guidance for ships in harbors or in dangerous areas, and for aircraft when landing or starting. Wherein, fixed, known active targets may be used for precise guidance. The same can be used for vehicles driving on dangerous but well defined routes, such as mining vehicles. Further, the devices according to the present invention may be used to detect rapidly approaching objects, such as cars, trains, flying objects, animals, or the like. Further, the devices according to the present invention can be used for detecting velocities or accelerations of objects, or to predict the movement of an object by tracking one or more of its position, speed, and/or acceleration depending on time.

Further, as outlined above, the devices according to the present invention may be used in the field of gaming. Thus, the devices according to the present invention can be passive for use with multiple objects of the same or of different size, color, shape, etc., such as for movement detection in combination with software that incorporates the movement into its content. In particular, applications are feasible in implementing movements into graphical output. Further, applications of the devices according to the present invention for giving commands are feasible, such as by using one or more of the devices according to the present invention for gesture or facial recognition. The devices according to the present invention may be combined with an active system in order to work under e.g. low light conditions or in other situations in which enhancement of the surrounding conditions is required. Additionally or alternatively, a combination of one or more devices according to the present invention with one or more IR or VIS light sources is possible. A combination of a detector according to the present invention with special devices is also possible, which can be distinguished easily by the system and its software, e.g. and not limited to, a special color, shape, relative position to other devices, speed of movement, light, frequency used to modulate light sources on the device, surface properties, material used, reflection properties, transparency degree, absorption characteristics, etc. The device can, amongst other possibilities, resemble a stick, a racquet, a club, a gun, a knife, a wheel, a ring, a steering wheel, a bottle, a ball, a glass, a vase, a spoon, a fork, a cube, a dice, a figure, a puppet, a teddy, a beaker, a pedal, a switch, a glove, jewelry, a musical instrument or an auxiliary device for playing a musical instrument, such as a plectrum, a drumstick or the like. Other options are feasible.

Further, the devices according to the present invention may be used to detect and or track objects that emit light by themselves, such as due to high temperature or further light emission processes. The light emitting part may be an exhaust stream or the like. Further, the devices according to the present invention may be used to track reflecting objects and analyze the rotation or orientation of these objects.

Further, the devices according to the present invention may generally be used in the field of building, construction and cartography. Thus, generally, one or more devices according to the present invention may be used in order to measure and/or monitor environmental areas, e.g. countryside or buildings. Therein, one or more devices according to the present invention may be combined with other methods and devices or can be used solely in order to monitor progress and accuracy of building projects, changing objects, houses, etc. The devices according to the present invention can be used for generating three-dimensional models of scanned environments, in order to construct maps of rooms, streets, houses, communities or landscapes, both from ground or air. Potential fields of application may be construction, cartography, real estate management, land surveying or the like. As an example, the devices according to the present invention may be used in vehicles capable of flight, such as drones or multicopters, in order to monitor buildings, chimneys, production sites, agricultural production environments such as fields, production plants, or landscapes, to support rescue operations, to support work in dangerous environments, to support fire brigades in a burning location indoors or outdoors, to find or monitor one or more persons, animals, or moving objects, or for entertainment purposes, such as a drone following and recording one or more persons doing sports such as skiing or cycling or the like, which could be realized by following a helmet, a mark, a beacon device, or the like. Devices according to the present invention could be used recognize obstacles, follow a predefined route, follow an edge, a pipe, a building, or the like, or to record a global or local map of the environment. Further, devices according to the present invention could be used for indoor or outdoor localization and positioning of drones, for stabilizing the height of a drone indoors where barometric pressure sensors are not accurate enough, or for the interaction of multiple drones such as concertized movements of several drones or recharging or refueling in the air or the like.

Further, the devices according to the present invention may be used within an interconnecting network of home appliances such as CHAIN (Cedec Home Appliances Interoperating Network) to interconnect, automate, and control basic appliance-related services in a home, e.g. energy or load management, remote diagnostics, pet related appliances, child related appliances, child surveillance, appliances related surveillance, support or service to elderly or ill persons, home security and/or surveillance, remote control of appliance operation, and automatic maintenance support. Further, the devices according to the present invention may be used in heating or cooling systems such as an air-conditioning system, to locate which part of the room should be brought to a certain temperature or humidity, especially depending on the location of one or more persons. Further, the devices according to the present invention may be used in domestic robots, such as service or autonomous robots which may be used for household chores. The devices according to the present invention may be used for a number of different purposes, such as to avoid collisions or to map the environment, but also to identify a user, to personalize the robot's performance for a given user, for security purposes, or for gesture or facial recognition. As an example, the devices according to the present invention may be used in robotic vacuum cleaners, floor-washing robots, dry-sweeping robots, ironing robots for ironing clothes, animal litter robots, such as cat litter robots, security robots that detect intruders, robotic lawn mowers, automated pool cleaners, rain gutter cleaning robots, window washing robots, toy robots, telepresence robots, social robots providing company to less mobile people, or robots translating and speech to sign language or sign language to speech. In the context of less mobile people, such as elderly persons, household robots with the devices according to the present invention may be used for picking up objects, transporting objects, and interacting with the objects and the user in a safe way. Further the devices according to the present invention may be used in robots operating with hazardous materials or objects or in dangerous environments. As a non-limiting example, the devices according to the present invention may be used in robots or unmanned remote-controlled vehicles to operate with hazardous materials such as chemicals or radioactive materials especially after disasters, or with other hazardous or potentially hazardous objects such as mines, unexploded arms, or the like, or to operate in or to investigate insecure environments such as near burning objects or post disaster areas, or for manned or unmanned rescue operations in the air, in the sea, underground, or the like.

Further, the devices according to the present invention may be used in household, mobile or entertainment devices, such as a refrigerator, a microwave, a washing machine, a window blind or shutter, a household alarm, an air condition devices, a heating device, a television, an audio device, a smart watch, a mobile phone, a phone, a dishwasher, a stove or the like, to detect the presence of a person, to monitor the contents or function of the device, or to interact with the person and/or share information about the person with further household, mobile or entertainment devices. Herein, the devices according to the present invention may be used to support elderly or disabled persons, blind persons, or persons with limited vision abilities, such as in household chores or at work such as in devices for holding, carrying, or picking objects, or in a safety system with optical and/or acoustical signals adapted for signaling obstacles in the environment.

The devices according to the present invention may further be used in agriculture, for example to detect and sort out vermin, weeds, and/or infected crop plants, fully or in parts, wherein crop plants may be infected by fungus or insects. Further, for harvesting crops, the devices according to the present invention may be used to detect animals, such as deer, which may otherwise be harmed by harvesting devices. Further, the devices according to the present invention may be used to monitor the growth of plants in a field or greenhouse, in particular to adjust the amount of water or fertilizer or crop protection products for a given region in the field or greenhouse or even for a given plant. Further, in agricultural biotechnology, the devices according to the present invention may be used to monitor the size and shape of plants.

Further, the devices according to the present invention may be combined with sensors to detect chemicals or pollutants, electronic nose chips, microbe sensor chips to detect bacteria or viruses or the like, Geiger counters, tactile sensors, heat sensors, or the like. This may for example be used in constructing smart robots which are configured for handling dangerous or difficult tasks, such as in treating highly infectious patients, handling or removing highly dangerous substances, cleaning highly polluted areas, such as highly radioactive areas or chemical spills, or for pest control in agriculture.

One or more devices according to the present invention can further be used for scanning of objects, such as in combination with CAD or similar software, such as for additive manufacturing and/or 3D printing. Therein, use may be made of the high dimensional accuracy of the devices according to the present invention, e.g. in x-, y- or z-direction or in any arbitrary combination of these directions, such as simultaneously. Within this regard, determining a distance of an illuminated spot on a surface which may provide reflected or diffusely scattered light from the detector may be performed virtually independent of the distance of the light source from the illuminated spot. This property of the present invention is in direct contrast to known methods, such as triangulation or such as time-of-flight (TOF) methods, wherein the distance between the light source and the illuminated spot must be known a priori or calculated a posteriori in order to be able to determine the distance between the detector and the illuminated spot. In contrast hereto, for the detector according to the present invention is may be sufficient that the spot is adequately illuminated. Further, the devices according to the present invention may be used for scanning reflective surfaces, such of metal surfaces, independent whether they may comprise a solid or a liquid surface. Further, the devices according to the present invention may be used in inspections and maintenance, such as pipeline inspection gauges. Further, in a production environment, the devices according to the present invention may be used to work with objects of a badly defined shape such as naturally grown objects, such as sorting vegetables or other natural products by shape or size or cutting products such as meat or objects that are manufactured with a precision that is lower than the precision needed for a processing step.

Further, the devices according to the present invention may be used in local navigation systems to allow autonomously or partially autonomously moving vehicles or multicopters or the like through an indoor or outdoor space. A non-limiting example may comprise vehicles moving through an automated storage for picking up objects and placing them at a different location. Indoor navigation may further be used in shopping malls, retail stores, museums, airports, or train stations, to track the location of mobile goods, mobile devices, baggage, customers or employees, or to supply users with a location specific information, such as the current position on a map, or information on goods sold, or the like.

Further, the devices according to the present invention may be used to ensure safe driving of motorcycles, such as driving assistance for motorcycles by monitoring speed, inclination, upcoming obstacles, unevenness of the road, or curves or the like. Further, the devices according to the present invention may be used in trains or trams to avoid collisions.

Further, the devices according to the present invention may be used in handheld devices, such as for scanning packaging or parcels to optimize a logistics process. Further, the devices according to the present invention may be used in further handheld devices such as personal shopping devices, RFID-readers, handheld devices for use in hospitals or health environments such as for medical use or to obtain, exchange or record patient or patient health related information, smart badges for retail or health environments, or the like.

As outlined above, the devices according to the present invention may further be used in manufacturing, quality control or identification applications, such as in product identification or size identification (such as for finding an optimal place or package, for reducing waste etc.). Further, the devices according to the present invention may be used in logistics applications. Thus, the devices according to the present invention may be used for optimized loading or packing containers or vehicles. Further, the devices according to the present invention may be used for monitoring or controlling of surface damages in the field of manufacturing, for monitoring or controlling rental objects such as rental vehicles, and/or for insurance applications, such as for assessment of damages. Further, the devices according to the present invention may be used for identifying a size of material, object or tools, such as for optimal material handling, especially in combination with robots. Further, the devices according to the present invention may be used for process control in production, e.g. for observing filling level of tanks. Further, the devices according to the present invention may be used for maintenance of production assets like, but not limited to, tanks, pipes, reactors, tools etc. Further, the devices according to the present invention may be used for analyzing 3D-quality marks. Further, the devices according to the present invention may be used in manufacturing tailor-made goods such as tooth inlays, dental braces, prosthesis, clothes or the like. The devices according to the present invention may also be combined with one or more 3D-printers for rapid prototyping, 3D-copying or the like. Further, the devices according to the present invention may be used for detecting the shape of one or more articles, such as for anti-product piracy and for anti-counterfeiting purposes.

Further, the devices according to the present invention may be used in the context of gesture recognition. In this context, gesture recognition in combination with devices according to the present invention may, in particular, be used as a human-machine interface for transmitting information via motion of a body, of body parts or of objects to a machine. Herein, the information may, preferably, be transmitted via a motion of hands or hand parts, such as fingers, in particular, by pointing at objects, applying sign language, such as for deaf people, making signs for numbers, approval, disapproval, or the like, by waving the hand, such as when asking someone to approach, to leave, or to greet a person, to press an object, to take an object, or, in the field of sports or music, in a hand or finger exercise, such as a warm-up exercise. Further, the information may be transmitted by motion of arms or legs, such as rotating, kicking, grabbing, twisting, rotating, scrolling, browsing, pushing, bending, punching, shaking, arms, legs, both arms, or both legs, or a combination of arms and legs, such as for a purpose of sports or music, such as for entertainment, exercise, or training function of a machine. Further, the information may be transmitted by motion of the whole body or major parts thereof, such as jumping, rotating, or making complex signs, such as sign language used at airports or by traffic police in order to transmit information, such as “turn right”, “turn left”, “proceed”, “slow down”, “stop”, or “stop engines”, or by pretending to swim, to dive, to run, to shoot, or the like, or by making complex motions or body positions such as in yoga, pilates, judo, karate, dancing, or ballet. Further, the information may be transmitted by using a real or mock-up device for controlling a virtual device corresponding to the mock-up device, such as using a mock-up guitar for controlling a virtual guitar function in a computer program, using a real guitar for controlling a virtual guitar function in a computer program, using a real or a mock-up book for reading an e-book or moving pages or browsing through in a virtual document, using a real or mock-up pen for drawing in a computer program, or the like. Further, the transmission of the information may be coupled to a feedback to the user, such as a sound, a vibration, or a motion.

In the context of music and/or instruments, devices according to the present invention in combination with gesture recognition may be used for exercising purposes, control of instruments, recording of instruments, playing or recording of music via use of a mock-up instrument or by only pretending to have a instrument present such as playing air guitar, such as to avoid noise or make recordings, or, for conducting of a virtual orchestra, ensemble, band, big band, choir, or the like, for practicing, exercising, recording or entertainment purposes or the like.

Further, in the context of safety and surveillance, devices according to the present invention in combination with gesture recognition may be used to recognize motion profiles of persons, such as recognizing a person by the way of walking or moving the body, or to use hand signs or movements or signs or movements of body parts or the whole body as access or identification control such as a personal identification sign or a personal identification movement.

Further, in the context of smart home applications or internet of things, devices according to the present invention in combination with gesture recognition may be used for central or non-central control of household devices which may be part of an interconnecting network of home appliances and/or household devices, such as refrigerators, central heating, air condition, microwave ovens, ice cube makers, or water boilers, or entertainment devices, such as television sets, smart phones, game consoles, video recorders, DVD players, personal computers, laptops, tablets, or combinations thereof, or a combination of household devices and entertainment devices.

Further, in the context of virtual reality or of augmented reality, devices according to the present invention in combination with gesture recognition may be used to control movements or function of the virtual reality application or of the augmented reality application, such as playing or controlling a game using signs, gestures, body movements or body part movements or the like, moving through a virtual world, manipulating virtual objects, practicing, exercising or playing sports, arts, crafts, music or games using virtual objects such as a ball, chess figures, go stones, instruments, tools, brushes.

Further, in the context of medicine, devices according to the present invention in combination with gesture recognition may be used to support rehabilitation training, remote diagnostics, or to monitor or survey surgery or treatment, to overlay and display medical images with positions of medical devices, or to overlay display prerecorded medical images such as from magnetic resonance tomography or x-ray or the like with images from endoscopes or ultra sound or the like that are recorded during an surgery or treatment.

Further, in the context of manufacturing and process automation, devices according to the present invention in combination with gesture recognition may be used to control, teach, or program robots, drones, unmanned autonomous vehicles, service robots, movable objects, or the like, such as for programming, controlling, manufacturing, manipulating, repairing, or teaching purposes, or for remote manipulating of objects or areas, such as for safety reasons, or for maintenance purposes.

Further, in the context of business intelligence metrics, devices according to the present invention in combination with gesture recognition may be used for people counting, surveying customer movements, areas where customers spend time, objects, customers test, take, probe, or the like.

Further, devices according to the present invention may be used in the context of do-it-yourself or professional tools, especially electric or motor driven tools or power tools, such as drilling machines, saws, chisels, hammers, wrenches, staple guns, disc cutters, metals shears and nibblers, angle grinders, die grinders, drills, hammer drills, heat guns, wrenches, sanders, engraivers, nailers, jig saws, buiscuit joiners, wood routers, planers, polishers, tile cutters, washers, rollers, wall chasers, lathes, impact drivers, jointers, paint rollers, spray guns, morticers, or welders, in particular, to support precision in manufacturing, keeping a minimum or maximum distance, or for safety measures.

Further, the devices according to the present invention may be used to aid visually impaired persons. Further, devices according to the present invention may be used in touch screen such as to avoid direct context such as for hygienic reasons, which may be used in retail environments, in medical applications, in production environments, or the like. Further, devices according to the present invention may be used in agricultural production environments such as in stable cleaning robots, egg collecting machines, milking machines, harvesting machines, farm machinery, harvesters, forwarders, combine harvesters, tractors, cultivators, ploughs, destoners, harrows, strip tills, broadcast seeders, planters such as potato planters, manure spreaders, sprayers, sprinkler systems, swathers, balers, loaders, forklifts, mowers, or the like.

Further, devices according to the present invention may be used for selection and/or adaption of clothing, shoes, glasses, hats, prosthesis, dental braces, for persons or animals with limited communication skills or possibilities, such as children or impaired persons, or the like. Further, devices according to the present invention may be used in the context of warehouses, logistics, distribution, shipping, loading, unloading, smart manufacturing, industry 4.0, or the like. Further, in a manufacturing context, devices according to the present invention may be used in the context of processing, dispensing, bending, material handling, or the like.

The devices according to the present invention may be combined with one or more other types of measurement devices. Thus, the devices according to the present invention may be combined with one or more other types of sensors or detectors, such as a time of flight (TOF) detector, a stereo camera, a lightfield camera, a lidar, a radar, a sonar, an ultrasonic detector, or interferometry. When combining devices according to the present invention with one or more other types of sensors or detectors, the devices according to the present invention and the at least one further sensor or detector may be designed as independent devices, with the devices according to the present invention being separate from the at least one further sensor or detector. Alternatively, the devices according to the present invention and the at least one further sensor or detector may fully or partially be integrated or designed as a single device.

Thus, as a non-limiting example, the devices according to the present invention may further comprise a stereo camera. As used herein, a stereo camera is a camera which is designed for capturing images of a scene or an object from at least two different perspectives. Thus, the devices according to the present invention may be combined with at least one stereo camera.

The stereo camera's functionality is generally known in the art, since stereo cameras generally are known to the skilled person. The combination with the devices according to the present invention may provide additional distance information. Thus, the devices according to the present invention may be adapted, in addition to the stereo camera's information, to provide at least one item of information on a longitudinal position of at least one object within a scene captured by the stereo camera. Information provided by the stereo camera, such as distance information obtained by evaluating triangulation measurements performed by using the stereo camera, may be calibrated and/or validated by using the devices according to the present invention. Thus, as an example, the stereo camera may be used to provide at least one first item of information on the longitudinal position of the at least one object, such as by using triangulation measurements, and the devices according to the present invention may be used to provide at least one second item of information on the longitudinal position of the at least one object. The first item of information and the second item of information may be used to improve accuracy of the measurements. Thus, the first item of information may be used for calibrating the second item of information or vice a versa. Consequently, the devices according to the present invention, as an example, may form a stereo camera system, having the stereo camera and the devices according to the present invention, wherein the stereo camera system is adapted to calibrate the information provided by the stereo camera by using the information provided by devices according to the present invention.

Consequently, additionally or alternatively, the devices according to the present invention may be adapted to use the second item of information, provided by the devices according to the present invention, for correcting the first item of information, provided by the stereo camera. Additionally or alternatively, the devices according to the present invention may be adapted to use the second item of information, provided by the devices according to the present invention, for correcting optical distortion of the stereo camera. Further, the devices according to the present invention may adapted to calculate stereo information provided by the stereo camera, and the second item of information provided by devices according to the present invention may be used for speeding up the calculation of the stereo information.

As an example, the devices according to the present invention may be adapted to use at least one virtual or real object within a scene captured by the devices according to the present invention for calibrating the stereo camera. As an example, one or more objects and/or areas and/or spots may be used for calibration. As an example, the distance of at least one object or spot may be determined by using the devices according to the present invention, and distance information provided by the stereo camera may be calibrated by using this distance is determined by using the devices according to the present invention. For instance, at least one active light spot of the devices according to the present invention may be used as a calibration point for the stereo camera. The active light spot, as an example, may move freely in the picture.

The devices according to the present invention may be adapted to continuously or discontinuously calibrate the stereo camera by using information provided by the active distance sensor. Thus, as an example, the calibration may take place at regular intervals, continuously or occasionally.

Further, typical stereo cameras exhibit measurement errors or uncertainties which are dependent on the distance of the object. This measurement error may be reduced when combined with information provided by the devices according to the present invention.

Combinations of stereo cameras with other types of distance sensors are generally known in the art. Thus, in D. Scaramuzza et al., IEEE/RSJ International Conference on Intelligent Robots and Systems, 2007. IROS 2007. Pages 4164-4169, an extrinsic self calibration of a camera and a 3D laser range finder from natural scenes is disclosed. Similarly, in D. Klimentjew et al., 2010 IEEE Conference on Multisensor Fusion and Integration for Intelligent Systems (MFI), pages 236-241, a multi sensor fusion of camera and 3D laser range finder for object recognition is disclosed. As the skilled person will recognize, the laser range finder in these setups known in the art may simply be replaced or complemented by at least one device according to the present invention, without altering the methods and advantages disclosed by these prior art documents. For potential setups of the stereo camera, reference may be made to these prior art documents. Still, other setups and embodiments of the at least one optional stereo camera are feasible.

Preferably, for further potential details of the optical detector, the method, the human-machine interface, the entertainment device, the tracking system, the camera and the various uses of the detector, in particular with regard to the transfer device, the transversal optical sensors, the evaluation device and, if applicable, to the longitudinal optical sensor, the modulation device, the illumination source and the imaging device, specifically with respect to the potential materials, setups and further details, reference may be made to one or more of WO 2012/110924 A1, US 2012/206336 A1, WO 2014/097181 A1, US 2014/291480 A1, and PCT patent application No. PCT/EP2016/051817, filed Jan. 28, 2016, the full content of all of which is herewith included by reference.

The above-described detector, the method, the human-machine interface and the entertainment device and also the proposed uses have considerable advantages over the prior art. Thus, generally, a simple and, still, efficient detector for an accurate determining a position of at least one object in space may be provided. Therein, as an example, three-dimensional coordinates of an object or a part thereof may be determined in a fast and efficient way.

As compared to devices known in the art, the detector as proposed provides a high degree of simplicity, specifically with regard to an optical setup of the detector. Thus, in principle, a simple combination of the colloidal quantum dots in combination with a particularly adapted setup and an appropriate evaluation device is sufficient for reliable high precision position detection, preferably within the infrared (IR) spectral range, in particular, within the near-infrared (NIR) spectral range. This high degree of simplicity, in combination with the possibility of high precision measurements, is specifically suited for machine control, such as in human-machine interfaces and, more preferably, in gaming, tracking, scanning, and a stereoscopic vision. Thus, cost-efficient entertainment devices may be provided which may be used for a large number of gaming, entertaining, tracking, scanning, and stereoscopic vision purposes.

Summarizing, in the context of the present invention, the following embodiments are regarded as particularly preferred:

Embodiment 1: A detector for an optical detection of at least one object, comprising:
at least one transversal optical sensor, the transversal optical sensor being adapted to determine a transversal position of a light beam traveling from the object to the detector, wherein the transversal position is a position in at least one dimension perpendicular to an optical axis of the detector, wherein the transversal optical sensor has at least one photovoltaic layer embedded between at least two conductive layers, wherein the photovoltaic layer comprises a plurality of quantum dots, wherein at least one of the conductive layers is at least partially transparent allowing the light beam to travel to the photovoltaic layer, wherein the transversal optical sensor further has at least one split electrode located at one of the conductive layers, wherein the split electrode has at least two partial electrodes adapted to generate at least one transversal sensor signal, wherein the at least one transversal sensor signal indicates the transversal position of the light beam in the photovoltaic layer; and
at least one evaluation device, wherein the evaluation device is designed to generate at least one item of information on a transversal position of the object by evaluating the at least one transversal sensor signal.

Embodiment 2: The detector according to the preceding embodiment, wherein the photovoltaic layer comprises a plurality of colloidal quantum dots (CQD).

Embodiment 3: The detector according to any one of the preceding embodiments, wherein the colloidal quantum dots (CQD) are obtainable from a colloidal film comprising the plurality of the quantum dots.

Embodiment 4: The detector according to the preceding embodiment, wherein the colloidal film comprises sub-micrometer-scale semiconductor crystals dispersed in a continuous phase comprising a medium.

Embodiment 5: The detector according to the preceding embodiment, wherein the medium comprises at least one nonpolar organic solvent.

Embodiment 6: The detector according to the preceding embodiment, wherein the nonpolar organic solvent is selected from the group comprising octane, toluene, cyclohexane, n-heptane, benzene, chlorobenzene, acetonitrile, dimethylformamide (DMF), and chloroform.

Embodiment 7: The detector according to any one of the three preceding embodiments, wherein the sub-micrometer-scale semiconductor crystals are, additionally, capped with cross-linking molecules, wherein the cross-linking molecules comprise an organic agent.

Embodiment 8: The detector according to the preceding embodiment, wherein the organic agent is selected from the group comprising thioles and amines.

Embodiment 9: The detector according to the preceding embodiment, wherein the organic agent is selected from the group comprising 1,2-ethanedithiol (edt), 1,2- and 1,3-benzenedithiol (bdt), and butylamine.

Embodiment 10: The detector according to any one of the seven preceding embodiments, wherein the colloidal quantum dots (CQD) are obtainable from a heat treatment of the colloidal film.

Embodiment 11: The detector according to the preceding embodiment, wherein the heat treatment of the colloidal film comprises drying of the colloidal film in a manner that the continuous phase is removed while the plurality of the quantum dots is maintained.

Embodiment 12: The detector according to any one of the two preceding embodiments, wherein the heat treatment comprises a applying a temperature from 50° C. to 250° C., preferably from 80° C. to 220° C., more preferred from 100° C. to 200° C., preferably in an air atmosphere.

Embodiment 13: The detector according to any one of the preceding embodiments, wherein the quantum dots comprise an inorganic photovoltaic material.

Embodiment 14: The detector according to the preceding embodiment, wherein the inorganic photovoltaic material comprises one or more of a group II-VI compound, a group III-V compound, a combination, a solid solution, or a doped variant thereof.

Embodiment 15: The detector according to the preceding embodiment, wherein the group II-VI compound is a chalcogenide.

Embodiment 16: The detector according to the preceding embodiment, wherein the chalcogenide is selected from the group consisting of: lead sulfide (PbS), lead selenide (PbSe), lead sulfoselenide (PbSSe), lead telluride (PbTe), copper indium sulfide (CIS), copper indium gallium selenide (CIGS), copper zinc tin sulfide (CZTS), copper zinc tin selenide (CZTSe), copper-zinc-tin sulfur-selenium (CZTSSe), cadmium telluride (CdTe), and a solid solution and/or a doped variant thereof.

Embodiment 17: The detector according to any one of the two preceding embodiments, wherein the group III-V compound is a pnictogenide.

Embodiment 18: The detector according to the preceding embodiment, wherein the pnictogenide is selected from the group consisting of: indium nitride (InN), gallium nitride (GaN), indium gallium nitride (InGaN), indium phosphide (InP), gallium phosphide (GaP), indium gallium phosphide (InGaP), indium arsenide (InAs), gallium arsenide (GaAs), indium gallium arsenide (InGaAs), indium antimonide (InSb), gallium antimonide (GaSb), indium gallium antimonide (InGaSb), indium gallium phosphide (InGaP), gallium arsenide phosphide (GaAsP), and aluminum gallium phosphide (AlGaP).

Embodiment 19: The detector according to any one of the preceding embodiments, wherein the quantum dots exhibit a size from 1 nm to 100 nm, preferably from 2 nm to 100 nm, more preferred from 2 nm to 15 nm.

Embodiment 20: The detector according to any one of the preceding embodiments, wherein the photovoltaic layer is provided as a thin film which comprises the plurality of the quantum dots.

Embodiment 21: The detector according to the preceding embodiment, wherein the thin film exhibits a thickness from 1 nm to 100 nm, preferably from 2 nm to 100 nm, more preferred from 2 nm to 15 nm, wherein the quantum dots exhibits a size below the thickness of the thin film.

Embodiment 22: The detector according to any one of the preceding embodiments, wherein the conductive layers exhibit a sheet resistance of 500 Ω/sq to 20 000 Ω/sq, preferably of 1000 Ω/sq to 15 000 Ω/sq.

Embodiment 23: The detector according to any one of the preceding embodiments, wherein the photovoltaic layer comprising the plurality of the quantum dots is arranged between a first conductive layer and a second conductive layer in a sandwich structure, wherein the first conductive layer exhibits at least partially transparent properties with respect to the incident light beam.

Embodiment 24: The detector according to the preceding embodiment, wherein the first conductive layer comprises an at least partially transparent semiconducting material.

Embodiment 25: The detector according to the preceding embodiment, wherein the semiconducting material is selected from the group comprising an at least partially transparent semiconducting metal oxide or a doped variant thereof.

Embodiment 26: The detector according to any one of the three preceding embodiments, wherein the semiconducting material is selected from indium tin oxide (ITO), fluorine-doped tin oxide (SnO2:F; FTO), magnesium oxide (MgO), aluminum zinc oxide (AZO), antimony tin oxide (SnO_{2/}Sb2O₅), a perovskite transparent conducting oxide, or a metal nanowire

Embodiment 27: The detector according to the preceding embodiment, wherein a blocking layer is arranged between the first conductive layer and the photovoltaic layer comprising the quantum dots, wherein the blocking layer comprises a thin film of an electrically conducting material.

Embodiment 28: The detector according to any one of the two preceding embodiments, wherein the blocking layer is an n-type semiconductor and comprises one or more of titanium dioxide (TiO₂) or zinc oxide (ZnO), or wherein the blocking layer is a p-type semiconductor comprising molybdenum oxide (MoO₃₋ₓ).

Embodiment 29: The detector according to any one of the six preceding embodiments, wherein the second conductive layer comprises an intransparent electrically conducting material.

Embodiment 30: The detector according to the preceding embodiment, wherein the second conductive layer comprises an evaporated metal layer, wherein the evaporated metal layer preferably comprises one or more of silver, aluminum, platinum, magnesium, chromium, titanium, or gold.

Embodiment 31: The detector according to any one of the eight preceding embodiments, wherein the second conductive layer comprises a layer of an electrically conducting polymer.

Embodiment 32: The detector according to the preceding embodiment, wherein the electrically conducting polymer is selected poly(3,4-ethylenedioxythiophene) (PEDOT) or from a dispersion of PEDOT and a polystyrene sulfonic acid (PEDOT:PSS).

Embodiment 33: The detector according to any one of the two preceding embodiments, wherein a split electrode comprising a metal contact is arranged on the second conductive layer.

Embodiment 34: The detector according to the preceding embodiment, wherein the metal contact comprises one or more of silver, copper, aluminum, platinum, magnesium, chromium, titanium, or gold.

Embodiment 35: The detector according to any one of the preceding embodiments, wherein the split electrode has at least four partial electrodes.

Embodiment 36: The detector according to any one of the preceding embodiments, wherein electrical currents through the partial electrodes are dependent on a position of the light beam in the photovoltaic layer.

Embodiment 37: The detector according to the preceding embodiment, wherein the transversal optical sensor is adapted to generate the transversal sensor signal in accordance with the electrical currents through the partial electrodes.

Embodiment 38: The detector according to any one of the preceding embodiments, wherein the detector, preferably the transversal optical sensor and/or the evaluation device, is adapted to derive the information on the transversal position of the object from at least one ratio of the currents through the partial electrodes.

Embodiment 39: The detector according to any one of the preceding embodiments, wherein the transversal sensor signal is selected from the group consisting of a current and a voltage or any signal derived thereof.

Embodiment 40: The detector according to any one of the preceding embodiments, furthermore comprising at least one illumination source.

Embodiment 41: The detector according to the preceding embodiment, wherein the illumination source is selected from: an illumination source, which is at least partly connected to the object and/or is at least partly identical to the object; an illumination source which is designed to at least partly illuminate the object with a primary radiation.

Embodiment 42: The detector according to the preceding embodiment, wherein the light beam is generated by a reflection of the primary radiation on the object and/or by light emission by the object itself, stimulated by the primary radiation.

Embodiment 43: The detector according to any one of the preceding embodiments, wherein the detector furthermore has at least one modulation device for modulating the illumination.

Embodiment 44: The detector according to any one the preceding embodiments, wherein the light beam is one of a non-modulated continuous-wave light beam or a modulated light beam.

Embodiment 45: The detector according to any one of the preceding embodiments, wherein the detector further comprises a longitudinal optical sensor, wherein the evaluation device is further designed to generate at least one item of information on a longitudinal position of the object by evaluating the longitudinal sensor signal of the longitudinal optical sensor.

Embodiment 46: The detector according to the preceding embodiment, wherein the longitudinal optical sensor has at least one sensor region, wherein the longitudinal optical sensor is designed to generate at least one longitudinal sensor signal in a manner dependent on an illumination of the sensor region by a light beam, wherein the longitudinal sensor signal, given the same total power of the illumination, is dependent on a beam cross-section of the light beam in the sensor region.

Embodiment 47: The detector according to any one of the two preceding embodiments, wherein the transversal sensor according to any one of the preceding embodiments is concurrently used as the longitudinal optical sensor.

Embodiment 48: The detector according to any one of the preceding embodiments, wherein the transversal optical sensor and the longitudinal optical sensor are stacked along the optical axis such that the light beam travelling along the optical axis both impinges the transversal optical sensor and the at least two longitudinal optical sensors, wherein the light beam subsequently passes through the transversal optical sensor and the at least two longitudinal optical sensors or vice versa.

Embodiment 49: The detector according to the preceding embodiment, wherein the light beam passes through the transversal optical sensor before impinging on one of the longitudinal optical sensors.

Embodiment 50: The detector according to any of the five preceding embodiments, wherein the longitudinal sensor signal is selected from the group consisting of a current and a voltage or any signal derived thereof.

Embodiment 51: The detector according to any one of the preceding embodiments, wherein the detector further comprises at least one imaging device.

Embodiment 52: The detector according to the preceding claim, wherein the imaging device is located in a position furthest away from the object.

Embodiment 53: The detector according to any of the two preceding embodiments, wherein the light beam passes through the at least one transversal optical sensor before illuminating the imaging device.

Embodiment 54: The detector according to any of the three preceding embodiments, wherein the imaging device comprises a camera.

Embodiment 55: The detector according to any of the four preceding embodiments, wherein the imaging device comprises at least one of: an inorganic camera; a monochrome camera; a multichrome camera; a full-color camera; a pixelated inorganic chip; a pixelated organic camera; a CCD chip, preferably a multi-color CCD chip or a full-color CCD chip; a CMOS chip; an IR camera; an RGB camera.

Embodiment 56: An arrangement comprising at least two detectors according to any one of the preceding embodiments.

Embodiment 57: The arrangement according to the preceding embodiment, wherein the arrangement further comprises at least one illumination source.

Embodiment 58: A human-machine interface for exchanging at least one item of information between a user and a machine, in particular for inputting control commands, wherein the human-machine interface comprises at least one detector according to any of the preceding embodiments relating to a detector, wherein the human-machine interface is designed to generate at least one item of geometrical information of the user by means of the detector wherein the human-machine interface is designed to assign to the geometrical information at least one item of information, in particular at least one control command.

Embodiment 59: The human-machine interface according to the preceding embodiment, wherein the at least one item of geometrical information of the user is selected from the group consisting of: a position of a body of the user; a position of at least one body part of the user; an orientation of a body of the user; an orientation of at least one body part of the user.

Embodiment 60: The human-machine interface according to any of the two preceding embodiments, wherein the human-machine interface further comprises at least one beacon device connectable to the user, wherein the human-machine interface is adapted such that the detector may generate an information on the position of the at least one beacon device.

Embodiment 61: The human-machine interface according to the preceding embodiment, wherein the beacon device comprises at least one illumination source adapted to generate at least one light beam to be transmitted to the detector.

Embodiment 62: An entertainment device for carrying out at least one entertainment function, in particular a game, wherein the entertainment device comprises at least one human-machine interface according to any of the preceding embodiments referring to a human-machine interface, wherein the entertainment device is designed to enable at least one item of information to be input by a player by means of the human-machine interface, wherein the entertainment device is designed to vary the entertainment function in accordance with the information.

Embodiment 63: A tracking system for tracking the position of at least one movable object, the tracking system comprising at least one detector according to any of the preceding embodiments referring to a detector, the tracking system further comprising at least one track controller, wherein the track controller is adapted to track a series of positions of the object, each comprising at least one item of information on a position of the object at a specific point in time.

Embodiment 64: The tracking system according to the preceding embodiment, wherein the tracking system further comprises at least one beacon device connectable to the object, wherein the tracking system is adapted such that the detector may generate an information on the position of the object of the at least one beacon device.

Embodiment 65: A scanning system for determining at least one position of at least one object, the scanning system comprising at least one detector according to any of the preceding embodiments relating to a detector, the scanning system further comprising at least one illumination source adapted to emit at least one light beam configured for an illumination of at least one dot located at least one surface of the at least one object, wherein the scanning system is designed to generate at least one item of information about the distance between the at least one dot and the scanning system by using the at least one detector.

Embodiment 66: The scanning system according to the preceding embodiment, wherein the illumination source comprises at least one artificial illumination source, in particular at least one laser source and/or at least one incandescent lamp and/or at least one semiconductor light source.

Embodiment 67: The scanning system according to any one of the two preceding embodiments, wherein the illumination source emits a plurality of individual light beams, in particular an array of light beams exhibiting a respective pitch, in particular a regular pitch.

Embodiment 68: The scanning system according to any one of the three preceding embodiments, wherein the scanning system comprises at least one housing.

Embodiment 69: The scanning system according to the preceding embodiment, wherein the at least one item of information about the distance between the at least one dot and the scanning system distance is determined between the at least one dot and a specific point on the housing of the scanning system, in particular a front edge or a back edge of the housing.

Embodiment 70: The scanning system according to any one of the two preceding embodiments, wherein the housing comprises at least one of a display, a button, a fastening unit, a leveling unit.

Embodiment 71: A camera for imaging at least one object, the camera comprising at least one detector according to any one of the preceding embodiments referring to a detector.

Embodiment 72: A method for an optical detection of at least one object, in particular by using a detector according to any of the preceding embodiments relating to a detector, comprising the following steps:
generating at least one transversal sensor signal by using at least one transversal optical sensor, the transversal optical sensor being adapted to determine a transversal position of a light beam traveling from the object to the detector, wherein the transversal position is a position in at least one dimension perpendicular to an optical axis of the detector, wherein the transversal optical sensor has at least one photovoltaic layer embedded between at least two conductive layers, wherein the photovoltaic layer comprises a plurality of quantum dots, wherein at least one of the conductive layers is at least partially transparent allowing the light beam to travel to the photovoltaic layer, wherein the transversal optical sensor further has at least one split electrode located at one of the conductive layers, wherein the split electrode has at least two partial electrodes adapted to generate at least one transversal sensor signal, wherein the at least one transversal sensor signal indicates the transversal position of the light beam in the photovoltaic layer; and
generating at least one item of information on a transversal position of the object by evaluating the at least one transversal sensor signal.

Embodiment 73: The method according to the preceding embodiment, wherein the photovoltaic layer is provided as colloidal quantum dots (CQD).

Embodiment 74: The method according to any one of the two preceding embodiments, wherein the colloidal quantum dots (CQD) are obtained from a colloidal film comprising the plurality of the quantum dots.

Embodiment 75: The method according to the preceding embodiment, wherein the colloidal film is provided in form of sub-micrometer-scale semiconductor crystals dispersed in a continuous phase comprising a medium.

Embodiment 76: The method according to the preceding embodiment, wherein the colloidal film is provided as a solution of the plurality of the quantum dots in an nonpolar organic solvent.

Embodiment 77: The method according to the preceding embodiment, wherein the solvent is selected from the group comprising octane, toluene, cyclohexane, chlorobenzene, n-heptane, benzene, dimethylformamide (DMF), acetonitrile, and chloroform,

Embodiment 78: The method according to the preceding embodiment, wherein the quantum dots are provided in a concentration from 10 mg/ml to 200 mg/ml, preferably from 50 mg/ml to 100 mg/ml, in the organic solvent.

Embodiment 79: The method according to the preceding embodiment, wherein the colloidal film is deposited onto a first conductive layer.

Embodiment 80: The method according to the preceding embodiment, wherein the first conductive layer comprises an at least partially transparent semiconducting material.

Embodiment 81: The method according to the preceding embodiment, wherein the at least partially transparent semiconducting material is selected from the group comprising an at least partially transparent semiconducting metal oxide, a doped variant thereof, or a metal nanowire.

Embodiment 82: The method according to the preceding embodiment, wherein the transparent conducting oxide is selected from indium tin oxide (ITO), fluorine doped tin oxide (FTO), aluminum doped zinc oxide (AZO), magnesium oxide (MgO), or a perovskite transparent conducting oxide.

Embodiment 83: The method according to any one of the four preceding embodiments, wherein the colloidal film is provided as at least two separate layers.

Embodiment 84: The method according to any one of the five preceding embodiments, wherein the colloidal film is provided by a deposition method, preferably by a coating method, more preferred by a spin-coating method.

Embodiment 85: The method according to the preceding embodiment, wherein the colloidal film undergoes a treatment with cross-linking molecules comprising an organic agent, whereby the sub-micrometer-scale semiconductor crystals are, additionally, capped with the cross-linking molecules.

Embodiment 86: The method according to the preceding embodiment, wherein the organic agent is preferably selected from the group comprising thioles and amines.

Embodiment 87: The method according to the preceding embodiment, wherein the organic agent is selected from the group comprising 1,2-ethanedithiol (edt), 1,2- and 1,3-benzenedithiol (bdt), and butylamine.

Embodiment 88: The method according to the preceding embodiment, wherein, after the treatment with the organic agent, the colloidal film is dried in a manner that the continuous phase is removed while the plurality of the quantum dots is maintained.

Embodiment 89: The method according to the preceding embodiment, wherein the colloidal film is dried at a temperature from 50° C. to 250° C., preferably from 80° C. to 220° C., more preferred from 100° C. to 200° C.

Embodiment 90: The method according to any one of the sixteen preceding embodiments, wherein a blocking layer is, firstly, directly deposited onto the first conductive layer until the CQD colloidal film is deposited onto the blocking layer, wherein the blocking layer comprises a thin film of an electrically conducting material, preferably titanium dioxide (TiO₂), zinc oxide (ZnO), or molybdenum oxide (MoO₃₋ₓ).

Embodiment 91: The method according to any one of the seventeen preceding embodiments, wherein a second conductive layer is deposited onto the colloidal film.

Embodiment 92: The method according to the preceding embodiment, wherein the second conductive layer comprises a metal layer.

Embodiment 93: The method according to the preceding embodiment, wherein the metal layer, particularly, comprises one or more of silver, copper aluminum, platinum, chromium, titanium, or gold.

Embodiment 94: The detector according to any one of the two preceding embodiments, wherein the second conductive layer comprises a layer of an electrically conducting polymer, in particular selected from poly(3,4-ethylenedioxythiophene) (PEDOT) or a dispersion of PEDOT and a polystyrene sulfonic acid (PEDOT:PSS).

Embodiment 95: The method according to the preceding embodiment, wherein the split electrode comprising a metal contact is arranged on the layer of the electrically conducting polymer, wherein the evaporated metal contacts, preferably, comprise one or more of silver, copper, aluminum, platinum, titanium, chromium, or gold.

Embodiment 96: A use of a detector according to any one of the preceding embodiments relating to a detector for a purpose of use selected from the group consisting of: a position measurement in traffic technology; an entertainment application; a security application; a human-machine interface application; a tracking application; a scanning application; a photography application; a cartography application; a mapping application for generating maps of at least one space; a homing or tracking beacon detector for vehicles; a mobile application; a webcam; an audio device; a dolby surround audio system; a computer peripheral device; a gaming application; a camera or video application; a surveillance application; an automotive application; a transport application; a logistics application; a vehicle application; an airplane application; a ship application; a spacecraft application; a robotic application; a medical application; a sports' application; a building application; a construction application; a manufacturing application; a machine vision application; a use in combination with at least one sensing technology selected from time-of-flight detector, radar, lidar, ultrasonic sensors, or interferometry.

### BRIEF DESCRIPTION OF THE FIGURES

Further optional details and features of the invention are evident from the description of preferred exemplary embodiments which follows in conjunction with the dependent claims. In this context, the particular features may be implemented alone or with features in combination. The invention is not restricted to the exemplary embodiments. The exemplary embodiments are shown schematically in the figures. Identical reference numerals in the individual figures refer to identical elements or elements with identical function, or elements which correspond to one another with regard to their functions.

Specifically, in the figures:

FIG. 1 shows an exemplary embodiment of a detector according to the present invention comprising a transversal optical sensor, wherein the transversal optical sensor has a photovoltaic layer comprising a plurality of quantum dots;

FIG. 2 shows a preferred embodiment of the transversal optical sensor having the photovoltaic layer comprising the plurality of the quantum dots;

FIG. 3 shows experimental results which demonstrate the applicability of the transversal optical sensor according to FIG. 2 as a position sensitive device;

FIG. 4 shows an exemplary embodiment of an optical detector, a detector system, a human-machine interface, an entertainment device, a tracking system and a camera according to the present invention.

### EXEMPLARY EMBODIMENTS

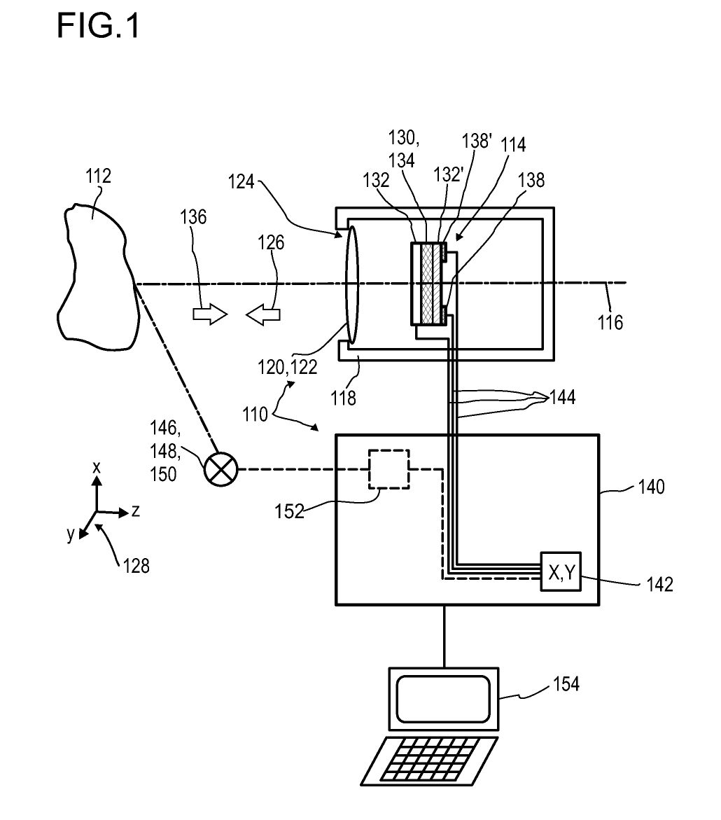

FIG. 1 illustrates, in a highly schematic fashion, an exemplary embodiment of an optical detector 110 according to the present invention, for determining a lateral position of at least one object 112. The optical detector 110 may preferably be adapted to be used as an infrared detector, particularly for the NIR spectral range, especially for wavelengths above 1000 nm. However, other embodiments are feasible.

The optical detector 110 comprises at least one transversal optical sensor 114, which, in this particular embodiment, is arranged along an optical axis 116 of the detector 110. Specifically, the optical axis 116 may be an axis of symmetry and/or rotation of the setup of the optical sensors 114. As described elsewhere in this document, the transversal optical sensor 114 may, in a particularly preferred embodiment, concurrently be employed as longitudinal optical sensor. The transversal optical sensor 114 may be located inside a housing 118 of the detector 110. Further, at least one transfer device 120 may be comprised, preferably a refractive lens 122. An opening 124 in the housing 118, which may, particularly, be located concentrically with regard to the optical axis 116, preferably defines a direction of view 126 of the detector 110. A coordinate system 128 may be defined, in which a direction parallel or antiparallel to the optical axis 116 is defined as a longitudinal direction, whereas directions perpendicular to the optical axis 116 may be defined as transversal directions. In the coordinate system 128, symbolically depicted in FIG. 1, a longitudinal direction is denoted by z and transversal directions are denoted by x and y, respectively. However, other types of coordinate systems 128 are feasible.

Further, the transversal optical sensor 114 in this embodiment has a photovoltaic layer 130 which is located between two conductive layers 132, 132′. In accordance with the present invention, the photovoltaic layer 130 comprises a plurality of quantum dots 134, in particular, a plurality of colloidal quantum dots (CQD). Preferably, the colloidal quantum dots (CQD) may be obtainable from a colloidal film which may comprise the plurality of the quantum dots 134. Herein, the conductive layer 132, which is located along the optical axis 116 of the optical detector 110 in a fashion that the incident light beam 136 first traverses the conductive layer 132 before it impinges the photovoltaic layer 130, is at least partially optically transparent, thus, allowing a light beam 136 to travel to the photovoltaic layer 130.

In order to generate at least one transversal sensor signal which may be indicative of the transversal position of the light beam 136 within the photovoltaic layer 130, the transversal optical sensor 114 is equipped with a split electrode being located at the other conductive layer 132′ which exhibits a sheet resistance of 500 Ω/sq to 20 000 Ω/sq, preferably of 1000 Ω/sq to 15 000 Ω/sq. The transversal sensor signal may, preferably, be selected from the group consisting of a current and a voltage or any signal derived thereof. As schematically illustrated in FIG. 1, the split electrode has at least two partial electrodes 138, 138′ which are arranged in a fashion that currents through the partial electrodes 138, 138′ may depend on a position of the light beam 136 within the photovoltaic layer 130. This kind of dependency can, in general, be achieved by Ohmic losses or resistive losses that may occur on a way from a location of a generation of electrical charges within the photovoltaic layer 130 to the partial electrodes 138, 138′. For this purpose, the other conductive 132′ layer may, preferably, exhibit a higher electrical resistance compared to the electrical resistance of the partial electrodes, whereby the Ohmic losses or the resistive losses may be accomplished.

The evaluation device 140 is, generally, designed to generate at least one item of information on a position of the object 112 by evaluating the sensor signal of the transversal optical sensor 114. For this purpose, the evaluation device 140 may comprise one or more electronic devices and/or one or more software components, in order to evaluate the sensor signals, which are symbolically denoted by a transversal evaluation unit 142 (denoted by “xy”). As will be explained below in more detail, the evaluation device 140 may be adapted to determine the at least one item of information on the transversal position of the object 112 by comparing more than one transversal sensor signals of the transversal optical sensor 114.

Herein, the transversal sensor signal may be transmitted to the evaluation device 140 via one or more signal leads 144. By way of example, the signal leads 144 may be provided and/or one or more interfaces, which may be wireless interfaces and/or wire-bound interfaces. Further, the signal leads 144 may comprise one or more drivers and/or one or more measurement devices for generating sensor signals and/or for modifying sensor signals.

The light beam 136 for illumining the sensor region of the transversal optical sensor 114 may be generated by a light-emitting object 112. Alternatively or in addition, the light beam 136 may be generated by a separate illumination source 146, which may include an ambient light source and/or an artificial light source, such as a laser diode 148, being adapted to illuminate the object 112 that the object 112 may be able to reflect at least a part of the light generated by the illumination source 146 in a manner that the light beam 136 may be configured to reach the sensor region of the transversal optical sensor 114, preferably by entering the housing 118 of the optical detector 110 through the opening 124 along the optical axis 116.

In a specific embodiment, the illumination source 146 may be a modulated light source 150, wherein one or more modulation properties of the illumination source 146 may be controlled by at least one optional modulation device 152. Alternatively or in addition, the modulation may be effected in a beam path between the illumination source 146 and the object 112 and/or between the object 112 and the transversal optical sensor 114. Further possibilities may be conceivable. This specific embodiment may allow distinguishing different light beams 136 by taking into account one or more of the modulation properties, in particular the modulation frequency, when evaluating the transversal sensor signal of the transversal optical sensor 114 for determining the at least one item of information on the position of the object 112.

Generally, the evaluation device 140 may be part of a data processing device 154 and/or may comprise one or more data processing devices 154. The evaluation device 140 may be fully or partially integrated into the housing 118 and/or may fully or partially be embodied as a separate device which is electrically connected in a wireless or wire-bound fashion to the transversal optical sensor 114. The evaluation device 140 may further comprise one or more additional components, such as one or more electronic hardware components and/or one or more software components, such as one or more measurement units and/or one or more evaluation units and/or one or more controlling units (not depicted here).

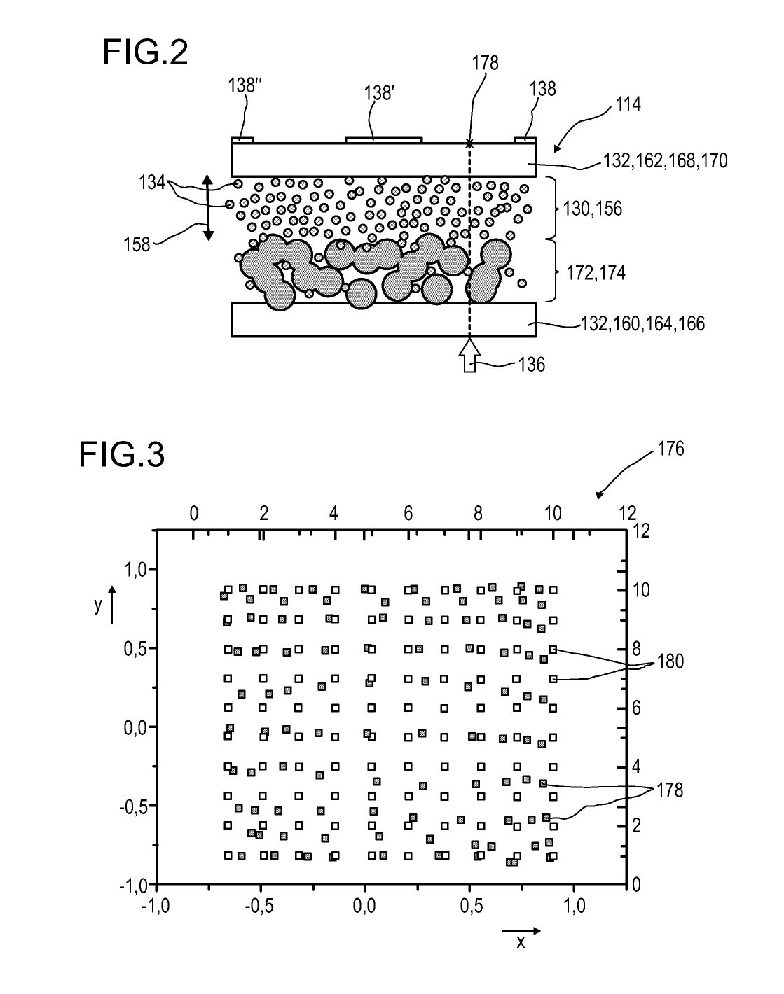

FIG. 2 illustrates a particularly preferred example of the transversal optical sensor 114 in which the photovoltaic layer 130 is provided in form of a colloidal film 156 which comprises the plurality of the quantum dots 134. In this particularly preferred embodiment, the quantum dots 134 comprise nanometer-scale crystals of lead sulfide (PbS), wherein other chalcogenides besides PbS may also be applicable for this purpose. Thus, the quantum dots 134 may comprise sub-micrometer-scale crystals of another inorganic photovoltaic material, preferably, selected from the group of a group II-VI compound, in particular a chalcogenide, a group III-V compound, in particular as pnictogenide, a combination, a solid solution, or a doped variant thereof. A number of preferred materials is described above on more detail. Herein, the nanometer-scale crystals exhibit a size from 1 nm to 100 nm, preferably from 2 nm to 100 nm, more preferred from 2 nm to 15 nm, while the colloidal film 156 which constitutes the photovoltaic layer 130 exhibits a thickness 158 from 1 nm to 100 nm, preferably from 2 nm to 100 nm, more preferred from 2 nm to 15 nm, wherein, however, the sizes of the quantum dots 134 is selected in a fashion that their size is below the thickness 158 of the colloidal film 156.

In the particularly preferred embodiment of the transversal optical sensor 114 as schematically illustrated in FIG. 2, the colloidal film 156 of the sub-micrometer-scale crystals of PbS which constitutes the photovoltaic layer 130 is sandwiched between the first conductive layer 160 and the second conductive layer 162. Herein, the first conductive layer 160 which is traversed by the incident light beam 136, preferably, comprises a layer of an electrically conducting and at least partially optically transparent layer 164, more preferred at least one transparent conductive oxide (TCO), in particular an FTO layer 166, wherein “FTO” denotes fluorine-doped tin oxide (SNO₂: F). However, other kinds of electrically conducting and optically transparent materials 164 may also be suitable as material for the first conductive layer 160, in particular one or more of, an indium-doped tin oxide (ITO), magnesium oxide (MgO), aluminum-doped zinc oxide (AZO), or, alternatively, metal nanowires, such as Ag or Cu nanowires.

In contrast hereto, the second conductive layer 162 comprises an electrically conducting polymer 168, preferably a poly(3,4-ethylenedioxythiophene) (PEDOT) layer 170, which was deposited onto the colloidal film 156. In order to achieve a good electrical contact to outside electrical means, a split electrode comprising at last two evaporated 200 nm silver (Ag) partial electrodes 138, 138′, 138″ have been deposited onto the PEDOT layer 170. Herein, the PEDOT layer 170 exhibits a sheet resistance of 500 Ω/sq to 20 000 Ω/sq, preferably of 1000 Ω/sq to 15 000 Ω/sq. Alternatively, the split electrode may be selected from the group comprising a platinum (Pt) electrode and a gold (Au) electrode. Herein, the split electrode may, preferably be arranged as a number of partial electrodes or in form of a metallic grid.

Further, a blocking layer 172 which, preferably, comprises a titanium dioxide (TiO₂) layer 174, was deposited onto the first conductive layer 160 before the colloidal film 156 was deposited on top of the blocking layer 172. In the embodiment of FIG. 2, the titanium dioxide layer 174 is an n-type semiconductor and comprises titanium dioxide (TiO₂) particles 176. Alternatively, the blocking layer 172 could also comprise zinc oxide (ZnO) or, wherein the blocking layer is a p-type semiconductor, molybdenum oxide (MoO₃). Herein, the blocking layer 172 comprising the TiO₂ may, in particular, assume a function of a hole blocking layer, thus, blocking a transport of electrons, whereby a recombination between holes and electrons within the blocking layer 172 may be excluded.

In this preferred example, the colloidal film 156 comprising the PbS quantum dots 134 having diameters of approximately 4 nm exhibits a considerably high optical absorption above 1000 nm. In order to achieve this result, a 50 mg/ml solution of PbS butylamine capped quantum dots 134 in an nonpolar organic solvent, preferably octane, have been provided, from which two subsequent layers have been formed on the FTO layer 166 by application of a deposition method, preferably by a spin-coating method with a rotation frequency from 1000 rpm to 6000 rpm, such as 5000 rpm. However, concentrations apart from 50 mg/ml may also be possible. Further, more than two layers of PbS CQD could also be used. Each of the two layers has individually been treated with ethanedithiol during a treatment time, preferably from 10 s to 10 min, more preferred from 10 s to 1 min, such as 30 s, before a drying step was performed for a drying time, preferably from 1 min to 2 h, more preferred from 10 min to 1 h, such as 30 min, at a drying temperature from 50° C. to 250° C., preferred from 80° C. to 200° C., such as 160° C. This kind of procedure turned out to be particularly advantageous with respect to obtaining a setup for the transversal optical sensor 114 with as few short circuits through the colloidal film 156 as possible. Thereafter, the PEDOT layer 170 was produced on top of the colloidal film 156. For this purpose, PEDOT PH1000 diluted with ethanol and isopropanol in a mixture of 1:1:1 was deposited onto the colloidal film 156, subjected to a spin with a rotation frequency from 1000 rpm to 6000 rpm, such as 3000 rpm, and, subsequently, dried at a temperature from 50° C. to 200° C., preferred from 80° C. to 150° C., such as 90° C., in a glove box for a drying time, preferably from 1 min to 2 h, more preferred from 10 min to 1 h, such as for 30 minutes, preferably, on a hot plate. Finally, silver (Ag) contacts having a thickness from 50 nm to 500 nm, preferred from 100 nm to 250 nm, such as 200 nm, have been deposited through evaporation onto the PEDOT layer 170 as the partial electrodes 138, 138′, 138″.

FIG. 3 shows experimental results which demonstrate the applicability of the transversal optical sensor 114 according to FIG. 2 for this purpose. Herein, the transversal optical sensor 114 comprising lead sulfide (PbS) as the quantum dots 134 within the photovoltaic layer 130, has been illuminated by the NIR laser diode 148 emitting a wavelength of 850 nm with a power of 1 mW at an applied voltage of 5 V. Further, a modulation frequency of 375 Hz for NIR the laser diode 148 has been used. Herein, a distance between the laser diode 148 and the photovoltaic layer 130 has been arranged to be 20 cm.

FIG. 3 schematically illustrates a sensor area 176 of the transversal optical sensor 114 in an x-direction and a y-direction. Herein, for a number of measurement points positions 178 as determined by application of the evaluation device 140 of the transversal optical sensor 114 according to the present invention have been compared with actual positions 180 which have been available by other kinds of methods, such as by employing geometrical considerations in using a known set-up of the transversal optical sensor 114.

In order to determine a position 178 of a measurement point by application of transversal optical sensor 114, the following procedure may be used. By way of example (not depicted here), a split electrode comprising four partial electrodes being located on top of the four rims of the second conductive layer 162 which has a square or a rectangular form is employed. Herein, by generating charges in the photovoltaic layer 130, electrode currents may be obtained, which, in each case, may be denoted by i₁ to i₄. As used herein, electrode currents i₁, i₂ may denote electrode currents through the partial electrodes located in y-direction and electrode currents i₃, i₄ may denote electrode currents through the partial electrodes located in x-direction. The electrode currents may be measured by one or more appropriate electrode measurement devices simultaneously or sequentially. By evaluating these electrode currents, the desired x- and y-coordinates of the position 178 of the measurement point under investigation, i.e. x₀ and y₀, may be determined. Thus, the following equations may be used:

$${x}_{0} = f ( \frac{{i}_{3} - {i}_{4}}{{i}_{3} + {i}_{4}} ) and {y}_{0} = f ( \frac{{i}_{1} - {i}_{2}}{{i}_{1} + {i}_{2}} ) .$$

Herein, ƒ might be an arbitrary known function, such as a simple multiplication of the quotient of the currents with a known stretch factor and/or an addition of an offset. Thus, generally, the electrode currents i₁ to i₄ might provide transversal sensor signals generated by the transversal optical sensor 114, whereas the evaluation device 140 might be adapted to generate information on a transversal position, such as at least one x-coordinate and/or at least one y-coordinate, by transforming the transversal sensor signals by using a predetermined or determinable transformation algorithm and/or a known relationship.

The results as shown in FIG. 3 demonstrate that for the number of the measurement points as presented there, the positions 178 as determined by the application of the transversal optical sensor 114 according to the present invention are reasonably comparable with the actual positions 180 acquired by another kinds of method.

As already mentioned above, the transversal sensor 114 according to the present invention may concurrently be employed as a longitudinal optical sensor adapted for determining the z-position. For this purpose, a sum of the electrode currents i₁, i₂ through the partial electrodes located in y-direction and of the electrode currents i₃, i₄ through the partial electrodes located in x-direction may be used in a preferred embodiment, wherein the electrode currents may be measured by one or more appropriate electrode measurement devices simultaneously or sequentially, for determining the z-coordinate. By evaluating these electrode currents, the desired z-coordinate of the position 178 of the measurement point under investigation, i.e. z₀, may be determined by using the following Equation:

z₀=ƒ(i₁+i₂+i₃+i₄)

For further details with respect to evaluating electrode currents in order to obtain the desired z-coordinate, reference may be made to WO 2012/ 110924 A1 or WO 2014/097181 A1.

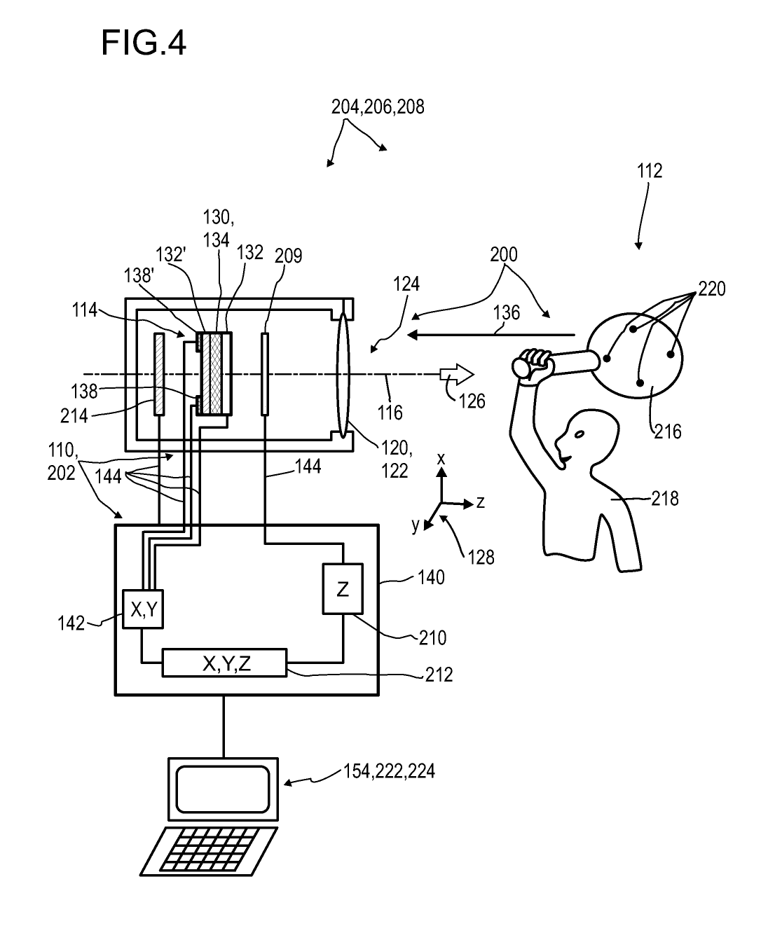

As a further example, FIG. 4 shows an exemplary embodiment of a detector system 200, comprising at least one optical detector 110, such as the optical detector 110 as disclosed in one or more of the embodiments shown in FIG. 1 or 2. Herein, the optical detector 110 may be employed as a camera 202, specifically for 3D imaging, which may be made for acquiring images and/or image sequences, such as digital video clips. Further, FIG. 4 shows an exemplary embodiment of a human-machine interface 204, which comprises the at least one detector 110 and/or the at least one detector system 200, and, further, an exemplary embodiment of an entertainment device 206 comprising the human-machine interface 204. FIG. 4 further shows an embodiment of a tracking system 208 adapted for tracking a position of at least one object 112, which comprises the detector 110 and/or the detector system 200. With regard to the optical detector 110, reference may be made to the full disclosure of this application. Basically, all potential embodiments of the detector 110 may also be embodied in the embodiment shown in FIG. 4.

As described above, the optical detector 110 may comprise a single transversal optical sensor 114 or, as e.g. disclosed in WO 2014/097181 A1, one or more transversal optical sensors 114, particularly, in combination with one or more longitudinal optical sensors 209. In a particularly preferred embodiment, the transversal optical sensor 114 may concurrently be employed as one of the longitudinal optical sensors 209 as described above. Alternatively or in addition, one or more at least partially longitudinal transversal optical sensors 209 may be located on a side of the stack of transversal optical sensors 114 facing towards the object 112. Alternatively or additionally, one or more longitudinal optical sensors 209 may be located on a side of the stack of transversal optical sensors 114 facing away from the object 112. As described in WO 2014/097181 A1, a use of two or, preferably, three longitudinal optical sensors 209 may support the evaluation of the longitudinal sensor signals without any remaining ambiguity. However, embodiments which may only comprise a single transversal optical 114 sensor but no longitudinal optical sensor 209 may still be possible, such as in a case wherein only determining the x- and y-coordinates of the object may be desired. The at least one optional longitudinal optical sensor 209 may further be connected to the evaluation device 140, in particular, by the signal leads 144.

Further, the at least one transfer device 120 may be provided, in particular as the refractive lens 122 or convex mirror. The optical detector 110 may further comprise the at least one housing 118 which, as an example, may encase one or more of components 114, 209.

Further, the evaluation device 140 may fully or partially be integrated into the optical sensors 114, 209 and/or into other components of the optical detector 110. The evaluation device 140 may also be enclosed into housing 118 and/or into a separate housing. The evaluation device 140 may comprise one or more electronic devices and/or one or more software components, in order to evaluate the sensor signals, which are symbolically denoted by the transversal evaluation unit 142 (denoted by “xy”) and a longitudinal evaluation unit 210 (denoted by “z”). By combining results derived by these evolution units 142, 210, a position information 212, preferably a three-dimensional position information, may be generated (denoted by “x, y, z”).

Further, the optical detector 110 and/or to the detector system 200 may comprise an imaging device 214 which may be configured in various ways. Thus, as depicted in FIG. 4, the imaging device 214 can for example be part of the detector 110 within the detector housing 118. Herein, the imaging device signal may be transmitted by one or more imaging device signal leads 144 to the evaluation device 140 of the detector 110. Alternatively, the imaging device 214 may be separately located outside the detector housing 118. The imaging device 214 may be fully or partially transparent or intransparent. The imaging device 214 may be or may comprise an organic imaging device or an inorganic imaging device. Preferably, the imaging device 214 may comprise at least one matrix of pixels, wherein the matrix of pixels may particularly be selected from the group consisting of: an inorganic semiconductor sensor device such as a CCD chip and/or a CMOS chip; an organic semiconductor sensor device.

In the exemplary embodiment as shown in FIG. 4, the object 112 to be detected, as an example, may be designed as an article of sports equipment and/or may form a control element 216, the position and/or orientation of which may be manipulated by a user 218. Thus, generally, in the embodiment shown in FIG. 4 or in any other embodiment of the detector system 200, the human-machine interface 204, the entertainment device 206 or the tracking system 208, the object 112 itself may be part of the named devices and, specifically, may comprise the at least one control element 216, specifically, wherein the at least one control element 216 has one or more beacon devices 220, wherein a position and/or orientation of the control element 216 preferably may be manipulated by user 218. As an example, the object 112 may be or may comprise one or more of a bat, a racket, a club or any other article of sports equipment and/or fake sports equipment. Other types of objects 112 are possible. Further, the user 218 may be considered as the object 112, the position of which shall be detected. As an example, the user 218 may carry one or more of the beacon devices 220 attached directly or indirectly to his or her body.

The optical detector 110 may be adapted to determine at least one item on a transversal position of one or more of the beacon devices 220 and, optionally, at least one item of information regarding a longitudinal position thereof. Particularly, the optical detector 110 may be adapted for identifying colors and/or for imaging the object 112, such as different colors of the object 112, more particularly, the color of the beacon devices 220 which might comprise different colors. The opening 124 in the housing 118, which, preferably, may be located concentrically with regard to the optical axis 116 of the detector 110, may preferably define a direction of a view 126 of the optical detector 110.

The optical detector 110 may be adapted for determining the position of the at least one object 112. Additionally, the optical detector 110, specifically an embodiment including the camera 202, may be adapted for acquiring at least one image of the object 112, preferably a 2D- or a 3D-image. As outlined above, the determination of a position of the object 112 and/or a part thereof by using the optical detector 110 and/or the detector system 200 may be used for providing a human-machine interface 204, in order to provide at least one item of information to a machine 222. In the embodiments schematically depicted in FIG. 4, the machine 222 may be or may comprise at least one computer and/or a computer system comprising the data processing device 154. Other embodiments are feasible. The evaluation device 140 may be a computer and/or may comprise a computer and/or may fully or partially be embodied as a separate device and/or may fully or partially be integrated into the machine 222, particularly the computer. The same holds true for a track controller 224 of the tracking system 208, which may fully or partially form a part of the evaluation device 140 and/or the machine 222.

Similarly, as outlined above, the human-machine interface 204 may form part of the entertainment device 206. Thus, by means of the user 218 functioning as the object 112 and/or by means of the user 218 handling the object 112 and/or the control element 216 functioning as the object 112, the user 218 may input at least one item of information, such as at least one control command, into the machine 222, particularly the computer, thereby varying the entertainment function, such as controlling the course of a computer game.

### LIST OF REFERENCE NUMBERS

110 detector

112 object

114 transversal optical sensor

116 optical axis

118 housing

120 transfer device

122 refractive lens

124 opening

126 direction of view

128 coordinate system

130 photovoltaic layer

132, 132′ conductive layer

134 quantum dot

136 light beam

138, 138′, 138″ partial electrode

140 evaluation device

142 transversal evaluation unit

144 signal leads

146 illumination source

148 laser diode

150 modulated illumination source

152 modulation device

154 data processing device

156 colloidal film

158 thickness

160 first conductive layer

162 second conductive layer

164 electrically conducting and at least partially optically transparent layer

166 fluorine-doped tin oxide (SnO₂: F; FTO) layer

168 electrically conductive polymer

170 poly(3,4-ethylenedioxythiophene) (PEDOT) layer

172 blocking layer

174 titanium dioxide layer

176 active area

178 determined position

180 actual position

200 detector system

202 camera

204 human-machine interface

206 entertainment device

208 tracking system

209 longitudinal optical sensor

210 longitudinal evaluation unit

212 position information

214 imaging device

216 control element

218 user

220 beacon device

222 machine

224 track controller

1-23 (canceled)

24. A detector for an optical detection of at least one object, comprising:
at least one transversal optical sensor configured to determine a transversal position of a light beam traveling from the object to the detector, wherein the transversal position is a position in at least one dimension perpendicular to an optical axis of the detector, wherein the transversal optical sensor includes at least one photovoltaic layer embedded between at least two conductive layers, wherein the photovoltaic layer includes a plurality of quantum dots, wherein at least one of the conductive layers is at least partially transparent allowing the light beam to travel to the photovoltaic layer, wherein the transversal optical sensor further includes at least one split electrode located at one of the conductive layers, wherein the split electrode includes at least two partial electrodes configured to generate at least one transversal sensor signal, wherein the at least one transversal sensor signal indicates the transversal position of the light beam in the photovoltaic layer; and
at least one evaluation device configured to generate at least one item of information on a transversal position of the object by evaluating the at least one transversal sensor signal.

25. The detector according to claim 24, wherein the photovoltaic layer includes a plurality of colloidal quantum dots.

26. The detector according to claim 25, wherein the colloidal quantum dots are obtainable from a colloidal film comprising the plurality of the quantum dots.

27. The detector according to claim 26, wherein the colloidal quantum dots are obtainable from a heat treatment of the colloidal film, wherein the heat treatment of the colloidal film comprises drying of the colloidal film such that a continuous phase is removed while the plurality of the quantum dots is maintained.

28. The detector according to claim 27, wherein the heat treatment comprises applying a temperature from 50° C. to 250° C.

29. The detector according to claim 24, wherein the quantum dots include an inorganic photovoltaic material.

30. The detector according to claim 29, wherein the inorganic photovoltaic material includes one or more of a group II-VI compound, a group III-V compound, a combination, a solid solution, or a doped variant thereof.

31. The detector according to claim 30, wherein the group II-VI compound is a chalcogenide, wherein the chalcogenide is selected from the group consisting of: lead sulfide (PbS), lead selenide (PbSe), lead sulfoselenide (PbSSe), lead telluride (PbTe), copper indium sulfide (CIS), copper indium gallium selenide (CIGS), copper zinc tin sulfide (CZTS), copper zinc tin selenide (CZTSe), copper-zinc-tin sulfur-selenium (CZTSSe), cadmium telluride (CdTe), and a solid solution and/or a doped variant thereof.

32. The detector according to claim 30, wherein the group III-V compound is a pnictogenide, wherein the pnictogenide is selected from the group consisting of: indium nitride (InN), gallium nitride (GaN), indium gallium nitride (InGaN), indium phosphide (InP), gallium phosphide (GaP), indium gallium phosphide (InGaP), indium arsenide (InAs), gallium arsenide (GaAs), indium gallium arsenide (InGaAs), indium antimonide (InSb), gallium antimonide (GaSb), indium gallium antimonide (InGaSb), indium gallium phosphide (InGaP), gallium arsenide phosphide (GaAsP), and aluminum gallium phosphide (AlGaP).

33. The detector according to claim 24, wherein the conductive layers exhibit a sheet resistance of 500 Ω/sq to 20 000 Ω/sq.

34. The detector according to claim 24, wherein electrical currents through the partial electrodes are dependent on a position of the light beam in the photovoltaic layer, wherein the transversal optical sensor is configured to generate the transversal sensor signal in accordance with the electrical currents through the partial electrodes.

35. The detector according to claim 34, wherein the detector is configured to derive the information on the transversal position of the object from at least one ratio of the currents through the partial electrodes.

36. The detector according to claim 24, further comprising:
at least one longitudinal optical sensor including at least one sensor region, wherein the longitudinal optical sensor is configured to generate at least one longitudinal sensor signal dependent on an illumination of the sensor region by the light beam, wherein the longitudinal sensor signal, given a same total power of the illumination, is dependent on a beam cross-section of the light beam in the sensor region,
wherein the evaluation device is further configured to generate at least one item of information on a longitudinal position of the object by evaluating the longitudinal sensor signal of the longitudinal optical sensor.

37. The detector according to claim 36, wherein the transversal optical sensor is concurrently used as the longitudinal optical sensor.

38. The detector according to claim 24, further comprising at least one illumination source.

39. The detector according to claim 24, further comprising at least one imaging device.

40. A human-machine interface for exchanging at least one item of information between a user and a machine, wherein the human-machine interface comprises:
at least one detector according to claim 24,
wherein the human-machine interface is configured to generate at least one item of geometrical information of the user by the detector wherein the human-machine interface is configured to assign to the geometrical information at least one item of information.

41. An entertainment device for carrying out at least one entertainment function, wherein the entertainment device comprises:
at least one human-machine interface according to claim 40,
wherein the entertainment device is configured to enable at least one item of information to be input by a player by the human-machine interface, wherein the entertainment device is configured to vary the entertainment function in accordance with the information.

42. A tracking system for tracking the position of at least one movable object, the tracking system comprising:
at least one detector according to claim 24;
at least one track controller, wherein the track controller is configured to track a series of positions of the object, each position comprising at least one item of information on at least a transversal position of the object at a specific point in time.

43. A scanning system for determining at least one position of at least one object, the scanning system comprising:
at least one detector according to claim 24;
at least one illumination source configured to emit at least one light beam configured for an illumination of at least one dot located at least one surface of the at least one object,
wherein the scanning system is configured to generate at least one item of information about the distance between the at least one dot and the scanning system by using the at least one detector.

44. A camera for imaging at least one object, the camera comprising at least one detector according to claim 24.

45. A method for an optical detection of at least one object, the method comprising:
generating at least one transversal sensor signal by using at least one transversal optical sensor, the transversal optical sensor configured to determine a transversal position of a light beam traveling from the object to the detector, wherein the transversal position is a position in at least one dimension perpendicular to an optical axis of the detector, wherein the transversal optical sensor includes at least one photovoltaic layer embedded between at least two conductive layers, wherein the photovoltaic layer includes a plurality of quantum dots, wherein at least one of the conductive layers is at least partially transparent allowing the light beam to travel to the photovoltaic layer, wherein the transversal optical sensor further includes at least one split electrode located at one of the conductive layers, wherein the split electrode includes at least two partial electrodes configured to generate at least one transversal sensor signal, wherein the at least one transversal sensor signal indicates the transversal position of the light beam in the photovoltaic layer; and
generating at least one item of information on a transversal position of the object by evaluating the at least one transversal sensor signal.

46. The use of a detector according to claim 24, for a purpose of use, selected from the group consisting of: a position measurement in traffic technology; an entertainment application; a security application; a human-machine interface application; a tracking application; a scanning application; a photography application; a cartography application; a mapping application for generating maps of at least one space; a homing or tracking beacon detector for vehicles; a mobile application; a webcam; an audio device; a Dolby surround audio system; a computer peripheral device; a gaming application; a camera or video application; a surveillance application; an automotive application; a transport application; a logistics application; a vehicle application; an airplane application; a ship application; a spacecraft application; a robotic application; a medical application; a sports' application; a building application; a construction application; a manufacturing application; a machine vision application; a use in combination with at least one sensing technology selected from time-of-flight detector, radar, Lidar, ultrasonic sensors, or interferometry.
